(19) United States
(12) Patent Application Publication
(10) Pub. No.: US 2026/0047140 A1
(43) Pub. Date: Feb. 12, 2026

(54) INSULATION FEATURE-BASED TRANSIENT VOLTAGE SUPPRESSOR DEVICES

(71) Applicant: Taiwan Semiconductor Manufacturing Company, Ltd., Hsinchu (TW)

(72) Inventors: Shih-Chang CHEN, Chiayi County (TW); Wen-Chao Shen, Zhubei City (TW)

(73) Assignee: Taiwan Semiconductor Manufacturing Company, Ltd., Hsinchu (TW)

(21) Appl. No.: 18/801,305

(22) Filed: Aug. 12, 2024

(51) Int. Cl. H01L 29/423; H01L 21/8238; H01L 27/02; H01L 27/092; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/017; H10D 84/038; H10D 84/85; H10D 89/601

(57) ABSTRACT

Semiconductor devices with insulation features and methods of fabrication are provided. A method includes forming a first source/drain feature and a second source/drain feature over a substrate, wherein the first source/drain feature and the second source/drain feature are separated by a gate structure; removing the gate structure to form a trench; forming an insulation feature in the trench; and forming a functional circuit over the substrate, wherein a shunt path parallel to the functional circuit is defined under the insulation feature and between the first source/drain feature and the second source/drain feature.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified top-down layout view of a semiconductor device, according to one or more aspects of the present disclosure;

FIG. 2 is a flow chart of a method of fabricating a semiconductor device according to one or more aspects of the present disclosure;

FIGS. 3A, 4A, 5A, 6A, 7A, 8A, 9A, and 10A provide cross-sectional views of an embodiment of a semiconductor device 300 along a plane substantially parallel to a plane defined by section X-X′ of FIG. 1, according to various stages of the method of FIG. 2;

FIGS. 3B, 4B, 5B, 6B, 7B, 8B, 9B, and 10B provide cross-sectional views of an embodiment of the semiconductor device 300 along a plane substantially parallel to a plane defined by section Y-Y′ of FIG. 1, according to various stages of the method of FIG. 2;

FIG. 11A is cross-sectional schematic view of an embodiment of a semiconductor device 300 along a plane substantially parallel to a plane defined by section X-X′ of FIG. 1, according to various stages of the method of FIG. 2;

FIG. 11B is a cross-sectional schematic view of the embodiment of FIG. 11A, taken along the plane B-B′ defined in FIG. 11C;

FIG. 11C is an overhead schematic view of the embodiment of FIG. 11A;

FIG. 12 is a circuit diagram illustrating the path of the TVS device of FIGS. 11A-11C;

FIG. 13 is a cross-sectional schematic view of an embodiment of a semiconductor device 300 along a plane substantially parallel to a plane defined by section X-X′ of FIG. 1, according to various stages of the method of FIG. 2;

FIGS. 14 and 15 are cross-sectional schematic views of an embodiment of a semiconductor device 300 along a plane substantially parallel to a plane defined by section X-X′ of FIG. 1, illustrating punch-through voltage behavior;

FIG. 16 is a current voltage diagram illustrating the behavior of a CPODE-based TVS device in accordance with embodiments herein;

FIG. 17A is cross-sectional schematic view of an embodiment of a semiconductor device 300 along a plane substantially parallel to a plane defined by section X-X′ of FIG. 1, according to various stages of the method of FIG. 2;

FIG. 17B is a cross-sectional schematic view of the embodiment of FIG. 17A, taken along the plane B-B′ defined in FIG. 17C;

FIG. 17C is an overhead schematic view of the embodiment of FIG. 17A;

FIG. 17D is cross-sectional schematic view of an embodiment of a semiconductor device 300 along a plane substantially parallel to a plane defined by section X-X′ of FIG. 1, according to various stages of the method of FIG. 2;

FIG. 18A is cross-sectional schematic view of an embodiment of a semiconductor device 300 along a plane substantially parallel to a plane defined by section X-X′ of FIG. 1, according to various stages of the method of FIG. 2;

FIG. 18B is a cross-sectional schematic view of the embodiment of FIG. 18A, taken along the plane B-B′ defined in FIG. 17C;

FIG. 18C is an overhead schematic view of the embodiment of FIG. 18A;

FIG. 19A is cross-sectional schematic view of an embodiment of a semiconductor device 300 along a plane substantially parallel to a plane defined by section X-X′ of FIG. 1, according to various stages of the method of FIG. 2;

FIG. 19B is a cross-sectional schematic view of the embodiment of FIG. 19A, taken along the plane B-B′ defined in FIG. 17C;

FIG. 19C is an overhead schematic view of the embodiment of FIG. 19A;

FIG. 20A is cross-sectional schematic view of an embodiment of a semiconductor device 300 along a plane substantially parallel to a plane defined by section X-X′ of FIG. 1, according to various stages of the method of FIG. 2;

FIG. 20B is an overhead schematic view of the embodiment of FIG. 20A;

FIG. 21A is cross-sectional schematic view of an embodiment of a semiconductor device 300 along a plane substantially parallel to a plane defined by section X-X′ of FIG. 1, according to various stages of the method of FIG. 2;

FIG. 21B is an overhead schematic view of the embodiment of FIG. 21A;

FIG. 22A is cross-sectional schematic view of an embodiment of a semiconductor device 300 along a plane substantially parallel to a plane defined by section X-X′ of FIG. 1, according to various stages of the method of FIG. 2;

FIG. 22B is an overhead schematic view of the embodiment of FIG. 22A;

FIGS. 23 and 24 are overhead schematic views of two embodiments of a semiconductor device 300, according to embodiments herein;

FIG. 25 is a current voltage diagram illustrating behavior of the devices of FIGS. 23 and 24;

FIGS. 26 and 27 are overhead schematic views of two embodiments of a semiconductor device 300, according to embodiments herein;

FIG. 28 is a current voltage diagram illustrating behavior of the devices of FIGS. 26 and 27;

FIGS. 29 and 30 are overhead schematic views of two embodiments of a semiconductor device 300, according to embodiments herein;

FIG. 31 is a current voltage diagram illustrating behavior of the devices of FIGS. 29 and 30; FIGS. 32 and 33 are overhead schematic views of two embodiments of a semiconductor device 300, according to embodiments herein;

FIG. 34 is a current voltage diagram illustrating behavior of the devices of FIGS. 32 and 33;

FIGS. 35 and 36 are overhead schematic views of two embodiments of a semiconductor device 300, according to embodiments herein; and

FIG. 37 is a flow chart of a method according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Certain embodiments herein are drawn to semiconductor devices in the form of multi-gate transistors. Multi-gate transistors include those transistors whose gate structures are formed on at least two-sides of a channel region. These multi-gate devices may include a P-type metal-oxide-semiconductor device or an N-type metal-oxide-semiconductor multi-gate device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanowires/nanosheets) associated with a single, contiguous gate structure. However, one of ordinary skill would recognize that the teaching can apply to a single channel (e.g., single nanowire/nanosheet) or any number of channels. While certain illustrations depict FinFET or GAA devices, the disclosure is not limited to such devices. For example, certain embodiments are drawn to planar semiconductor devices. One of ordinary skill may recognize other examples of semiconductor devices that may benefit from aspects of the present disclosure.

Certain embodiments herein include a continuous poly on diffusion edge (CPODE) process to form an insulation feature. A “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulation features. The CPODE process may provide an insulation feature between neighboring active regions, and thus neighboring transistors, by performing a dry etching process along an active edge (e.g., at a boundary of adjacent active regions) to form a cut region and filling the cut region with a dielectric, such as silicon nitride (SiN). More specifically, the CPODE process may provide an insulation feature between neighboring source/drain features, by performing a dry etching process along an active edge (e.g., at a boundary of adjacent active regions) to form a cut region and filling the cut region with a dielectric, such as silicon nitride (SiN).

Before the CPODE process, the active edge may include a dummy GAA structure having a gate stack and a plurality of channels (e.g., nanowire/nanosheet channels). In addition, inner spacers may be disposed between adjacent channels at lateral ends of the plurality of channels. In various examples, source/drain epitaxial (epi) layers of adjacent active regions are disposed on either side of the dummy GAA structure (formed at the active edge), such that the adjacent source/drain epi layers are in contact with the inner spacers and plurality of channels of the dummy GAA structure. Just prior to the CPODE etching process, a gate etching process may be performed to remove the gate layer from the dummy GAA structure.

In certain embodiments, the source/drain features adjacent to the insulation feature are terminals that are in electrical communication with a functional circuit. Specifically, a shunt path parallel to the functional circuit is defined between the terminals. The shunt path extends from source/drain feature to source/drain feature under the CPODE feature. Therefore, a punch-through voltage may be selected and defined by the structure of the CPODE feature. In other words, the CPODE feature may be formed with a desired depth, a desired lateral width (in a lateral direction from source/drain region to source/drain region), and a desired longitudinal length (in a direction perpendicular to the lateral direction) to define the desired punch-through voltage.

In other words, the source/drain features and insulation feature form a transient voltage suppressor (TVS) device, such as a diode. In the normal range of the working voltage of the functional circuit, the transient voltage suppressor appears as high impedance. Only when a surge exceeds a preset limit does the transient voltage suppressor become conductive, abruptly limiting the voltage from rising above the limit.

The transient voltage suppressor is formed parallel to the functional circuit to provide protection to the functional circuit from high voltages. When the applied voltage exceeds a maximum allowed transient voltage, i.e., the punch-through voltage, the current is conducted through the source/drain features to ground.

In certain embodiments, the transient voltage suppressor junction punch-through mechanism is formed by a CPODE feature overlying semiconductor material.

Unlike conventional transient voltage suppressors, embodiments herein do not rely on extra implantation processes to define N/P junctions to define and set the punch-through voltage. Due to the use of a CPODE-based feature to define the punch-through voltage rather than implant regions, processing may be simplified and costs may be reduced. Also, use of an insulation feature to provide transient voltage suppressor isolation, rather than a large doping distance, may remove processing limitations.

Further, the use of the CPODE-based feature to define the punch-through voltage enables tuning of the maximum transient voltage, at the scale of tens of nanometers, without extra implantation processing. The maximum allowed transient voltage may be tuned by changing the dimensions of the CPODE features, such as depth, width, and length. Thus, the tunability transient voltage suppressor allowance transient current and maximum allowance transient voltage can be achieved purely by layout, without any extra implantation process.

In certain embodiments, the scale of a CPODE-based transient voltage suppressor can be several tens of nanometer level and the chip area needed to form the CPODE-based transient voltage suppressor may be much less than needed by implant-based TVS structures. For example, the CPODE-based transient voltage suppressor may have an area of from 10 to 20 nanometers.

Thus, embodiments herein provide for designs of various kinds of small transient voltage suppressor structures with selectable desired maximum transient voltages that are compatible with small features of functional circuits.

In certain embodiments, the two terminals formed by source/drain features may be adjacent to the natural end of the active regions, or oxide definition (OD) regions; adjacent to polysilicon on OD edge (“PODE”) structures; adjacent to floating dummy gates; or adjacent to other structures. The source/drain features may be formed in planar transistors, FinFETs, gate-all-around devices including nano-structures such as nano-sheets or nano-rods, or other devices.

Embodiments of the present disclosure offer advantages over the existing art, though it is understood that other embodiments may offer different advantages, not all advantages are necessarily discussed herein, and no particular advantage is required for all embodiments.

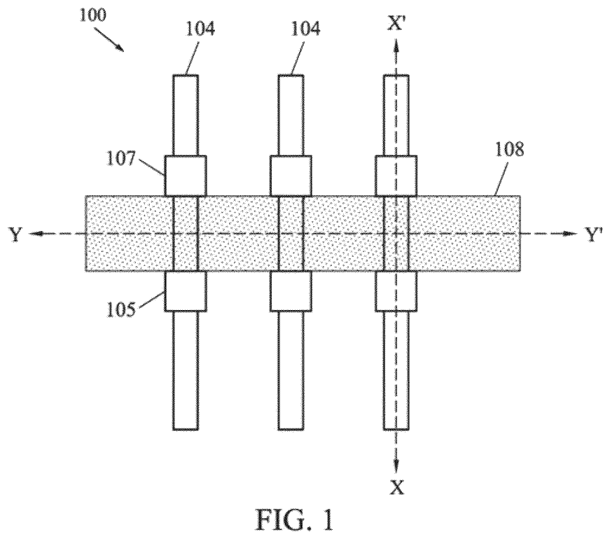

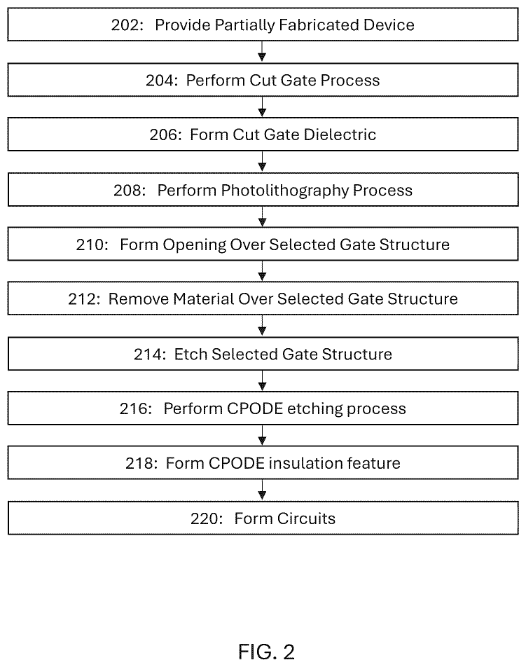

For purposes of the discussion that follows, FIG. 1 provides a simplified top-down layout view of a semiconductor device 100. In various embodiments, the semiconductor device 100 is a multi-gate device and may include a FinFET device, a GAA transistor, or other type of multi-gate device. The multi-gate device 100 may include a plurality of fin elements 104 extending from a substrate, a gate structure 313 disposed over and around the fin elements 104, and source/drain features 105, 107, where the source/drain features 105, 107 are formed in, on, and/or surrounding the fins 104. A channel region of the multi-gate device 100, which may include a plurality of semiconductor channel layers (e.g., when the multi-gate device 100 includes a GAA transistor), is disposed within the fins 104, underlying the gate structure 313, along a plane substantially parallel to a plane defined by section X-X′ of FIG. 1. In some embodiments, sidewall spacers may also be formed on sidewalls of the gate structure 313. Various other features of the multi-gate device 100 are discussed in more detail below with reference to the method of FIG. 2.

Referring to FIG. 2, illustrated therein is a method 200 for fabricating a semiconductor device 300 (e.g., which may include a multi-gate device) using a CPODE process, in accordance with various embodiments. The method 200 is discussed below with reference to a GAA device having a channel region that may be referred to as a nanosheet and which may include various geometries (e.g., cylindrical, bar-shaped) and dimensions. However, it will be understood that aspects of the method 200, including the disclosed CPODE process, may be equally applied to other types of devices without departing from the scope of the present disclosure. In some embodiments, the method 200 may be used to fabricate the device 100, described above with reference to FIG. 1. Thus, one or more aspects discussed above with reference to the device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

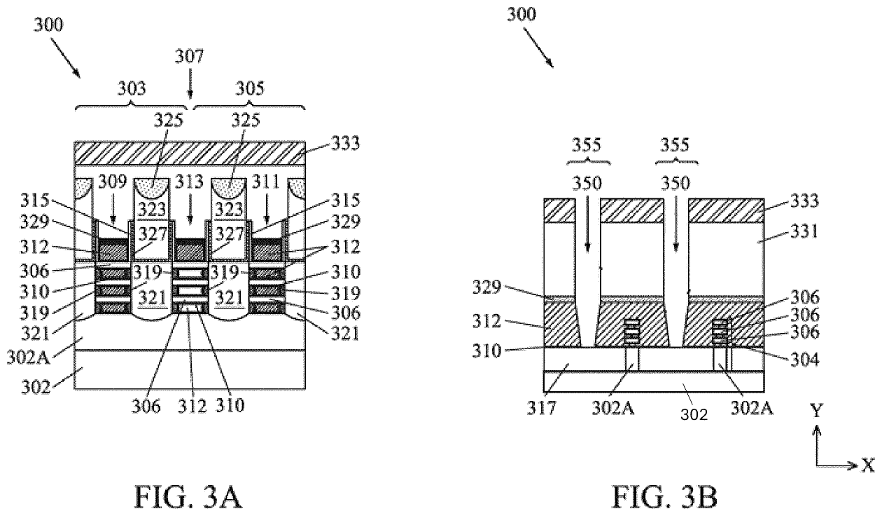

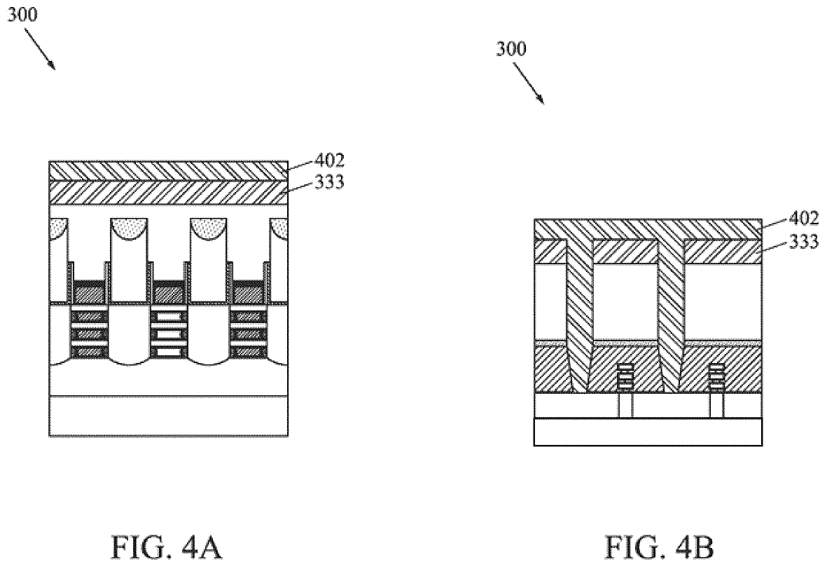

The method 200 is described below with reference to FIG. 3A/3B, 4A/4B, 5A/5B, 6A/6B, 7A/7B, 8A/8B, 9A/9B, and 10A/10B which illustrate the semiconductor device 300 at various stages of fabrication according to the method 200. FIGS. 3A, 4A, 5A, 6A, 7A, 8A, 9A, and 10A provide cross-sectional views of an embodiment of the semiconductor device 300 along a plane substantially parallel to a plane defined by section X-X′ of FIG. 1. Further, FIGS. 3B, 4B, 5B, 6B, 7B, 8B, 9B, and 10B provide cross-sectional views of an embodiment of the semiconductor device 300 along a plane substantially parallel to a plane defined by section Y-Y′ of FIG. 1.

Further, the semiconductor device 300 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the semiconductor device 300 includes a plurality of semiconductor devices (e.g., transistors), including PFETs, NFETs, etc., which may be interconnected. Moreover, it is noted that the process steps of method 200, including any descriptions given with reference to the figures are merely exemplary and are not intended to be limiting beyond what is specifically recited in the claims that follow.

The method 200 begins at block 202 where a partially fabricated device is provided. Referring to the example of FIGS. 3A and 3B, in an embodiment of block 202, a device 300 includes a first active region 303, a second active region 305, and an active edge 307 that is defined at a boundary of the first active region 303 and the second active region 305. In some embodiments, the first active region 303 includes a first GAA device 309, the second active region 305 includes a second GAA device 311, and the active edge 307 includes a dummy GAA structure 313, as described below. In accordance with embodiments of the present disclosure, a CPODE process may provide an insulation feature between the first active region 303 and the second active region 305, and thus between the first and second GAA devices 309, 311, by performing a dry etching process along the active edge 307 to form a cut region and filling the cut region with a dielectric, as described in more detail below. Each of the first GAA device 309, the second GAA device 311, and the dummy GAA structure 313 are formed on a substrate 302 having fins 304.

Block 202 includes providing the substrate 302. In some embodiments, the substrate 302 may be a semiconductor substrate such as a silicon substrate. The substrate 302 may include various layers, including conductive or insulating layers formed on a semiconductor substrate. The substrate 302 may include various doping configurations depending on design requirements as is known in the art. The substrate 302 may also include other semiconductors such as germanium, silicon carbide (SiC), silicon germanium (SiGe), or diamond. Alternatively, the substrate 302 may include a compound semiconductor and/or an alloy semiconductor. Further, the substrate 302 may optionally include an epi layer, may be strained for performance enhancement, may include a silicon-on-insulator (SOI) structure, and/or have other suitable enhancement features.

In certain embodiments, block 202 includes forming a stack of epitaxial layers over the substrate. The stack includes first epitaxial layers of a first composition interposed by second epitaxial layers of a second composition. The first and second composition may be different. Embodiments are possible including those that provide for a first composition and a second composition having different oxidation rates and/or etch selectivity. In an embodiment, the first epitaxial layers are silicon germanium (SiGe) and the second epitaxial layers are silicon.

In certain embodiments, block 202 includes patterning the substrate and the overlying stack of epitaxial layers to form the fin elements 104. Further, block 202 may include forming shallow trench isolation (STI) features (also denoted as STI features) in trenches adjacent to the sides and ends of each fin element 104 with a dielectric layer. The STI features may be formed by first filling the trenches around each fin element 104 with a dielectric material layer to cover top surfaces and sidewalls of the fin element 104. The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP) followed by a recess process to form the shallow trench isolation (STI) features. Any suitable etching technique may be used to recess the STI features including dry etching, wet etching, RIE, and/or other etching methods, and in an exemplary embodiment, an anisotropic dry etching is used to selectively remove the dielectric material of the isolation features without etching the fin element 104.

Block 202 further includes forming sacrificial (dummy) gate structures 313, any suitable number of sacrificial gate structures may be formed. Each sacrificial gate structure 313 protrudes upwardly in the Z-direction from the substrate and extends lengthwise in the Y-direction. In FIG. 1, additional sacrificial gate structures would be spaced apart along the X-direction.

The sacrificial gate structures 313 are formed over portions of the fin element 104 which are to be channel regions. The sacrificial gate structures 313 may extend over a number of adjacent fin elements 104. The sacrificial gate structures 313 lie directly over and define the channel regions of the semiconductor devices to be formed. Each of the sacrificial gate structures 313 may include a sacrificial gate dielectric and a sacrificial gate electrode over the sacrificial gate dielectric.

The sacrificial gate structures 313 are formed by first blanket depositing a sacrificial gate dielectric layer over the fin elements 104. A sacrificial gate electrode layer is then blanket deposited on the sacrificial gate dielectric layer and over the fin elements 104. The sacrificial gate dielectric layer includes silicon oxide, silicon nitride, or a combination thereof. The thickness of the sacrificial gate electrode layer is in a range from about one hundred nanometers to about two hundred nanometers in some embodiments. The sacrificial gate electrode layer includes silicon such as polycrystalline silicon or amorphous silicon. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer is formed over the sacrificial gate electrode layer. The mask layer may include a layer of silicon oxide and a layer of silicon nitride. Subsequently, a patterning operation is performed on the mask layer, and the sacrificial gate electrode layers and the sacrificial gate dielectric layer are patterned into the sacrificial gate structures 313.

After forming the sacrificial gate structures 313, each fin element 104 is partially uncovered or exposed on opposite sides of the sacrificial gate structures 313, thereby defining source/drain (S/D) regions. In this disclosure, “source/drain region(s)” or “source/drain feature(s)” may refer to a source or a drain, individually or collectively dependent upon the context.

Block 202 may further include forming sidewall spacers 315 on sidewalls of the sacrificial gate structures 313 and sidewalls of the fin elements 104 by depositing spacer materials, followed by an etching. The sidewall spacers 315 may include spacer material such as silicon oxide, silicon nitride, silicon carbide, silicon oxynitride, SiCN films, silicon oxycarbide, SiOCN films, and/or combinations thereof.

Block 202 may further include etching-back (e.g., anisotropically) to expose, and remove, portions of the fin elements 104 adjacent to and not covered by the sacrificial gate structure 313 (e.g., source/drain regions). After removal of the portions of fin elements 104, the liner material layer and the dielectric material layer remains on the sidewalls of the sacrificial gate structure 313 as the gate sidewall spacers, and on the sidewalls of the fins as fin sidewall spacers.

Block 202 may further include forming inners spacers. For example, the second epitaxial layers in the fin elements 104 may be etched. In an exemplary embodiment, an SiGe etchback process is removed to laterally recess the second layers. As a result, pockets are formed laterally adjacent to the second layers. Then, a material for forming the inner spacers 319 is deposited. For example, the inner spacers 319 may be formed from silicon oxides, silicon nitrides, silicon carbides, silicon carbide nitride, silicon oxide carbide, silicon carbide oxynitride, and/or other suitable dielectric materials. The inner spacers 319 may be formed by ALD or any other suitable method. After depositing the material forming inner spacers 319, the material may be trimmed from the sidewalls of first epitaxial layers.

Block 202 may also include forming source/drain features 321. In exemplary embodiments, the source/drain features 321 are formed by epitaxial growth. In exemplary embodiments, the source/drain features 321 are strained source/drain features. In exemplary embodiments, the source/drain features 321 may include an n-type epitaxial material source/drain features and a p-type epitaxial material source/drain features. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

Block 202 may include capping the source/drain features 321 with dielectric. Specifically, a dielectric liner 327, such as a contact etch stop layer (CESL), may be formed over source/drain features 321 and along the sides of the spacers 315. Further, a dielectric 323 may be formed over the liner 327 over the source/drain features 321. In exemplary embodiments, the dielectric 323 is a first interlayer dielectric layer (ILD). The dielectric 323 may be silicon oxide or other suitable dielectric material. In certain embodiments, the ILD dielectric 323 is the same material as the sidewall spacers 315. In certain embodiments, the dielectric liner 327 is a dielectric, such as silicon nitride or another suitable material.

Block 202 may further include opening and removing selected sacrificial gate structures, including removing both the sacrificial gate dielectric and the sacrificial gate electrode. Specifically, a chemical mechanical planarization (CMP) process may be performed to uncover the selected sacrificial gate structures. The selected sacrificial gate structures are then removed to form gate cavities bounded by the sidewall spacers 315.

Block 202 further includes removing the first epitaxial layers under the removed selected sacrificial gate structures. As a result, gaps are formed between the second epitaxial layers. In this manner, the second epitaxial layers are formed as vertically-spaced apart semiconductor nanosheet channel layers 306.

Block 202 also includes completing a replacement metal gate process. In exemplary embodiments, the replacement metal gate process includes forming a gate dielectric layer 310 in the gate cavities and in the gaps under nanosheet channel layers 306, and forming a gate electrode material 312 over the gate dielectric layer 310 to fill the gate cavities and fill the gaps.

An exemplary gate dielectric layer(s) 310 is deposited conformally. The gate dielectric 310 may be formed on the semiconductor nanosheet channel layers 306, and the gate electrode material 312 may be formed on the gate dielectric layer(s) 310. Thus, each semiconductor nanosheet channel layer 306 is wrapped in gate dielectric 310 and surrounded by gate electrode material 312.

In accordance with some embodiments, the gate dielectric layer(s) 310 may include silicon oxide, silicon nitride, or multilayers thereof. In some embodiments, the gate dielectric layer(s) 310 is a high-k dielectric material, and in these embodiments, the gate dielectric layer(s) 310 may have a k value greater than about 7.0, and may include a metal oxide or a silicate of Hf, Al, Zr, La, Mg, Ba, Ti, Pb, and combinations thereof. The formation methods of the gate dielectric layer(s) 310 may include Molecular-Beam Deposition (MBD), ALD, PECVD, and the like.

The gate electrode material 312 is deposited over the gate dielectric layer(s) 310 and fills the remaining portion of the gate cavity. The gate electrode material 312 may be a metal-containing material such as TiN, TaN, TaC, Co, Ru, Al, combinations thereof, or multi-layers thereof. For example, although a single gate electrode material is illustrated, any number of work function tuning layers may be deposited.

The replacement metal gate process may further include removing excess portions of the gate dielectric layer(s) 310 and the gate electrode material 312 located over the top surface of the ILD 323. For example, a planarization process, such as a CMP process, may be performed to remove the excess portions of the gate dielectric layer(s) 310 and the gate electrode material 312.

The remaining portions of material of the gate dielectric layer(s) 310 and the gate electrode material 312 thus form the replacement metal gate structure of the resulting devices 309 and 311. The gate dielectric layer(s) 310 and gate electrode material 312 may be collectively referred to as a “gate,” a “gate stack,” or a “gate structure.” Each gate structure may extend along sidewalls of a channel region of the fin structures.

Block 202 also includes forming a gate capping layer 325 over the gate structures. For example, the gate capping layer 325 may be a hard mask layer 325. The gate capping layer 325 may be formed by initially depositing a dielectric material over the gates. In some embodiments, the gate caps 325 are formed using a dielectric material such as a silicon nitride (SiN), oxide (OX), silicon oxynitride (SiON), silicon oxycarbonitride (SiOCN), silicon carbonitride (SiCN), or the like. According to some embodiments, the gate caps 325 are formed using a metal oxide of materials such as zirconium (Zr), hafnium (Hf), aluminum (Al), or the like. Furthermore, the gate caps 325 may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate caps 325 may be planarized using a planarization process such as a chemical mechanical polishing process.

Block 202 may further include deposited additional material layer 331 over the device 300, including over the caps 325.

Also, block 202 may include forming a dielectric layer 333 may be formed over the material layer 331. In some embodiments, the dielectric layer 333 includes SiN. The dielectric layer 333 may also be used as a hard mask layer.

With reference to the X and Y dimensions of the nanosheet channel layers 306 from an end-view of the nanosheet channel layers 306 (e.g., FIG. 3B), the X-dimension may be equal to about five to fourteen nm, and the Y-dimension may be equal to about five to eight nm. In some cases, the X-dimension of the nanosheet channel layers 306 is substantially the same as the Y-dimension of the nanosheet channel layers 306. In some cases, a spacing (e.g., along the Y-direction) between adjacent nanosheet channel layers 306 is equal to about four to eight nm.

As shown in FIGS. 3A and 3B, each of the fins 304 may include a substrate portion 302A formed from the substrate 302 and the nanosheet channel layers 306. It is noted that while the fins 304 are illustrated as including three nanosheet channel layers 306, this is for illustrative purposes only and is not intended to be limiting beyond what is specifically recited in the claims. It can be appreciated that any number of nanosheet channel layers 306 can be formed, where for example, the number of nanosheet channel layers 306 depends on the desired number of channels regions for the GAA device (e.g., the device 300). In some embodiments, the number of nanosheet channel layers 306 is between three and ten.

In some embodiments, source/drain features 321 are formed in source/drain regions adjacent to and on either side of the gate structure of each of the first GAA device 309 and the second GAA device 311 and over the substrate portion 302A. As a result, the dummy GAA structure 313 is disposed between a first source/drain feature 321 of the first GAA device 309 (in the first active region 303) and a second source/drain feature 321 of the second GAA device 311 (in the second active region 305). As shown, the source/drain features 321 of the first GAA device 309 are in contact with the inner spacers 319 and nanosheet channel layers 306 of the first GAA device 309, and the source/drain features 321 of the second GAA device 311 are in contact with the inner spacers 319 and nanosheet channel layers 306 of the second GAA device 311. Moreover, the source/drain features 321 (of the first and second GAA devices 309, 311) disposed on either side of the dummy GAA structure 313 are in contact with the inner spacers 319 and nanosheet channel layers 306 of the dummy GAA structure 313.

In various examples, the source/drain features 321 include semiconductor epi layers such as Ge, Si, GaAs, AlGaAs, SiGe, GaAsP, SiP, or other suitable material, which may be formed by one or more epitaxial processes. In some embodiments, the source/drain features 321 may be in-situ doped during the epi process. For example, in some embodiments, epitaxially grown SiGe source/drain features may be doped with boron. In some cases, epitaxially grown Si source/drain features may be doped with carbon to form Si:C source/drain features, phosphorous to form Si:P source/drain features, or both carbon and phosphorous to form SiCP source/drain features. In some embodiments, the source/drain features 321 are not in-situ doped, and instead an implantation process is performed to dope the source/drain features 321. In some embodiments, formation of the source/drain features 321 may be performed in separate processing sequences for each of N-type and P-type source/drain features.

In certain embodiments, method 200 then proceeds to optional block 204 where a cut gate or cut metal gate (CMG) process is performed. With reference to FIG. 3B, in an embodiment of block 204 and after forming the dielectric layer 333, a cut metal gate process is performed to isolate the metal layers 312 of adjacent structures. By way of example, a photolithography and etch process may be performed to etch portions of the dielectric layer 333, the material layer 331, the metal layer 329, the metal layer 312, and the high-K gate dielectric layer 310 to form trenches 350 in cut metal gate regions 355. In some embodiments, formation of the trenches 350 exposes portions of the underlying STI features 317. In various examples, the trenches 350 may be etched using a dry etch (e.g., reactive ion etching), a wet etch, or a combination thereof.

The method 200 then proceeds to block 206 where a refill process is performed. With reference to FIG. 3A/3B and 4A/4B, in an embodiment of block 206, a refill process is used to form a dielectric layer 402 over the device 300, including over the dielectric layer 333. The dielectric layer 402 is also used to fill the previously formed trenches 350 and electrically isolate the metal layers 312 of adjacent structures. In some embodiments, the dielectric layer 402 includes SiN. Alternatively, in some cases, the dielectric layer 402 may include SiO2, silicon oxynitride, FSG, a low-k dielectric, combinations thereof, and/or other suitable materials known in the art. In various examples, the dielectric layer 402 may be deposited by a CVD process, an SACVD process, a flowable CVD process, an ALD process, a PVD process, and/or other suitable process. In some cases, after depositing the dielectric layer 402, a chemical mechanical polishing (CMP) process may be performed to remove excess material and planarize a top surface of the device 300.

The method 200 then proceeds to block 208 where a photolithography (photo) process is performed. With reference to FIG. 4A/4B and 5A/5B, in an embodiment of block 208, a photoresist (resist) layer is deposited (e.g., using a spin-coating process) over the device 300 and patterned to form a patterned resist layer 502 that exposes a portion of the dielectric layer 402. In various embodiments, the photo process used to form the patterned resist layer 502 may also include other steps such as soft baking, mask aligning, exposure, post-exposure baking, developing, rinsing, drying (e.g., spin-drying and/or hard baking), other suitable lithography processes, and/or combinations thereof. In some embodiments, the photo process of block 208 may include a CPODE photo process, where the patterned resist layer 502 provides an opening 504 in a CPODE region 506 that exposes the portion of the dielectric layer 402. In addition, the CPODE region 506 may include the active edge 307 and the dummy GAA structure 313, discussed above with reference to FIG. 3A.

The method 200 then proceeds to block 210 where etching and resist removal processes are performed. With reference to FIG. 5A/5B and 6A/6B, in an embodiment of block 210, an etching process is performed to remove portions of the dielectric layer 402 and the dielectric layer 333 (e.g., in a region exposed by the opening 504 in the patterned resist layer 502) to form an opening 604. Thus, in some examples, the etching process of block 210 may be referred to as a SiN etching process, a hard mask etching process, or a SiN hard mask etching process. In various embodiments, the opening 604 formed by the etching process may expose a portion of the material layer 331 within the CPODE region 506. In some examples, the etching process may include a dry etching process, a wet etching process, and/or a combination thereof. After the etching process, and in a further embodiment of block 210, the patterned resist layer 502 may be removed, for example, by way of a solvent, resist stripper, ashing, or other suitable technique.

The method 200 then proceeds to block 212 where an etching process is performed. With reference to FIG. 6A/6B and 7A/7B, in an embodiment of block 212, an etching process is performed to remove portions of the material layer 331 (e.g., in a region exposed by the opening 604) to form an opening 704. In various embodiments, for example when the material layer 331 includes silicon (Si), the etching process of block 212 may include a Si etching process or a Si dry etching process. In some examples, the opening 704 formed by the etching process of block 212 may expose the dummy gate GAA structure 313 within the CPODE region 506. In particular, the opening 704 may expose the metal layer 329, portions of the spacer layer 315, and in some cases portions of the CESL 327 within the CPODE region 506. In some examples, the etching process of block 212 may include a dry etching process, a wet etching process, and/or a combination thereof.

The method 200 then proceeds to block 214 where a gate etching process is performed. With reference to FIG. 7A/7B and 8A/8B, in an embodiment of block 214, the gate etching process includes removal of the layers 312, 329 without removing gate dielectric layer 310 of the dummy GAA structure 313. Stated another way, the wet etching process selectively removes the layers 312, 329 without removing the gate dielectric layer 310. Thus, the wet etching process of block 214 may be referred to as a selective etching process or a selective wet etching process. It is noted that the wet etching process may remove the layers 312 from a top portion of the dummy GAA structure 313, as well as between adjacent channels of the nano sheet channel layers 306.

The method 200 then proceeds to block 216 where a CPODE etching process is performed. With reference to FIG. 8A/8B and 9A/9B, in an embodiment of block 216, the CPODE etching process etches the device 300 through the opening 804 within the CPODE region 506 to remove the gate structure 313 selected for removal (labeled in FIG. 7A) to form a trench 904 with an extension 906 that may extend into the underlying substrate 302. In some cases, the CPODE etching process includes a dry etching process. In some embodiments, the CPODE etching process removes portions of the nanosheet channel layers 306, the inner spacers 319, the high-K gate dielectric layer 310, an interfacial layer, if present, and underlying substrate 302 within the CPODE region 506 that are not protected by (disposed directly below) the spacer layer 315.

The method 200 then proceeds to block 218 where a refill process is performed. With reference to FIG. 9A/9B and 10A/10B, in an embodiment of block 218, a refill process is used to form an insulation layer 1002 over the device 300 and within the trench 904 formed by the CPODE etching process. The insulation layer 1002, and more generally the CPODE process described herein, thus provides an isolation region between the first active region 303 and the second active region 305, including between the first and second GAA devices 309, 311, by performing the CPODE etching process along the active edge 307 to form a cut region (the trench 904) and filling the cut region with the insulation layer 1002. In some embodiments, the insulation layer 1002 includes SiN. Alternatively, in some cases, the insulation layer 1002 may include SiO2, silicon oxynitride, FSG, a low-k dielectric, combinations thereof, and/or other suitable materials known in the art. In various examples, the insulation layer 1002 may be deposited by a CVD process, an SACVD process, a flowable CVD process, an ALD process, a PVD process, and/or other suitable process. In some cases, after depositing the insulation layer 1002, a CMP process may be performed to remove excess material and planarize a top surface of the device 300.

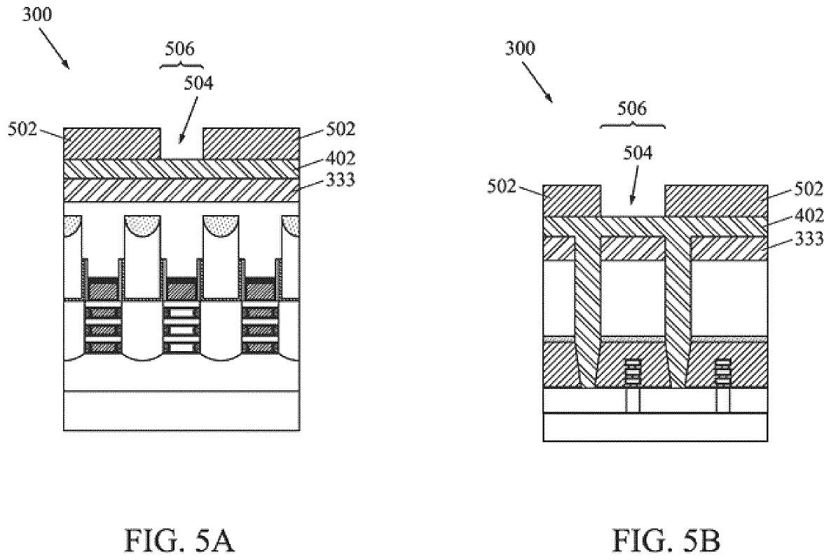

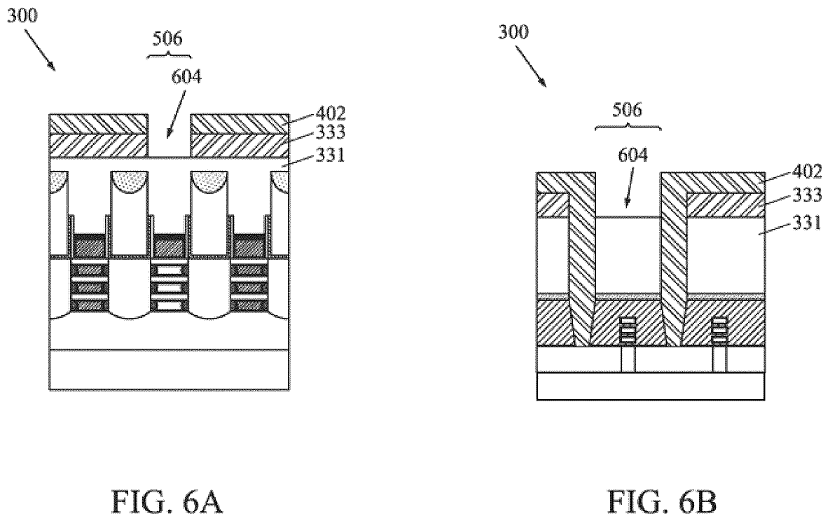

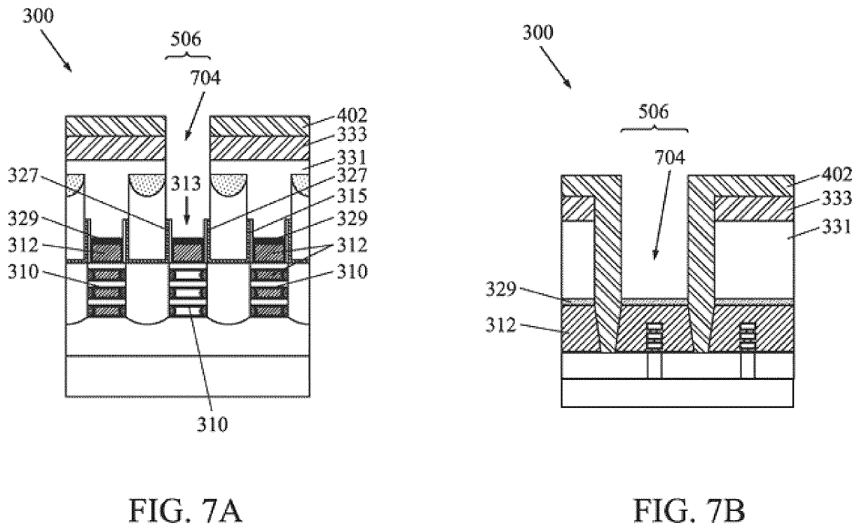

FIGS. 3A-10B indicate that the gate structure 313 selected for removal may be located between two other adjacent gate structures 309 and 311. However, it is contemplated that gate structure 313 instead be located between two ends 103 of a fin element 104 such that each source/drain feature 321, including a first source/drain feature 3121 and a second source/drain feature 3122, is laterally adjacent to an STI feature 317. Such an embodiment is shown in FIG. 11.

The method 200 may continue at block 220 with forming circuits in the semiconductor device. For example, block 220 may include forming overlying dielectric layers, contact openings, contact metal, as well as various contacts/vias/lines and multilayer interconnect features (e.g., metal layers and interlayer dielectrics) on the substrate 302, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200. Further, while the method 200 has been shown and described as including the device 300 having a GAA device, it will be understood that other device configurations are possible. In some embodiments, the method 200 may be used to fabricate FinFET devices or other multi-gate devices.

FIGS. 11A, 11B, and 11C illustrate the structure of the device 300 of FIGS. 10A and 10B, during further processing. FIG. 11A is a cross-sectional schematic similar to FIG. 10A. FIG. 11B is cross-sectional view along a Y-axis indicated by line B-B′, i.e., passing through contact 1011 rather than through insulation feature 1002 as in the previous Y-cut views. FIG. 11C is an overhead schematic.

As shown in FIGS. 11A, 11B, and 11C, forming circuits at block 220 includes forming a first source/drain contact 1011 electrically connected to the first source/drain feature 3211, and forming a second source/drain contact 1012 electrically connected to the second source/drain feature 3212. As further shown, the first source/drain contact 1011 is electrically connected to a first node 911 and the second source/drain contact 1012 is electrically connected to a second node 912.

A transient voltage suppressor (TVS) device in the form of a shunt path 1100 is formed between the first source/drain feature 3211 and the second source/drain feature 3212. The shunt path 1100 extends through the fin element 104 and/or substrate 302 and under the CPODE insulation feature 1002.

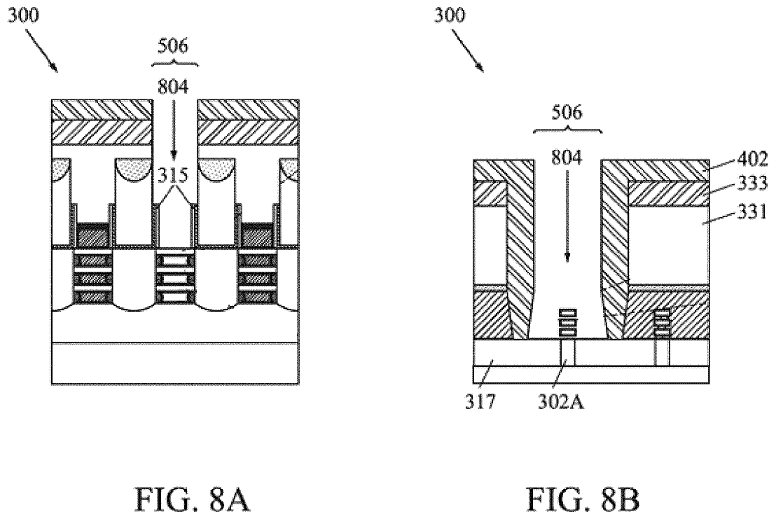

Referring to FIG. 12, forming circuits at block 220 may include forming a functional circuit 1200 over the substrate and forming the TVS device 1100 as a shunt path parallel to the functional circuit 1200 defined under the insulation feature and between the first source/drain feature 3211 and the second source/drain feature 3212. In FIG. 12, the nodes 911 and 912 are shown to be connected to the functional circuit 1200 formed over the substrate 302. As shown, the TVS device 1100 is parallel to the functional circuit 1200. Node 912 may be connected to a voltage source (Vin) 1400 and node 911 may be connected to a ground 1300.

The TVS device 1100 appears as high impedance in the normal range of the signal working voltage that passes to functional circuit 1200. When the voltage exceeds a preset limit, the TVS device 1100 become conductive, abruptly limiting the voltage from rising above the preset limit, as the current flows through the TVS device 1100 to ground 1300.

The preset limit depends on properties of the structure of the CPODE insulation feature 1002 relative to the source/drain features 3211 and 3212. For example the depth of the CPODE insulation feature 1002 will affect the preset limit.

As shown in FIG. 11A, the CPODE insulation feature 1002 has a lowest point or surface defining a horizontal bottom plane 1003. Further, the fin element 104 has an uppermost point or surface defining a horizontal upper plane 1004. The CPODE insulation feature 1002 is formed with a depth D1 from the upper surface plane 1004 to the horizontal bottom plane 1003. While the depth of the CPODE insulation feature 1002 is defined in relation to the uppermost surface of the fin element 104, the depth may be measured in reference to any component of device 300. For example, the depth may be measured from the bottom surface of the source/drain regions 321. Generally, increasing the depth of the CPODE insulation feature 1002 may increase the punch-through voltage at which the TVS device 1100 becomes active.

In certain embodiments, depth D1 is at least 1 nanometer (nm), such as at least 2 nm, at least 3 nm, at least 4 nm, at least 5 nm, at least 6 nm, at least 7 nm, at least 8 nm, at least 9 nm, at least 10 nm, at least 12 nm, at least 14 nm, at least 16 nm, at least 18 nm, at least 20 nm, at least 25 nm, at least 30 nm, at least 35 nm, at least 40 nm, at least 45 nm, at least 50 nm, at least 55 nm, at least 60 nm, at least 65 nm, at least 70 nm, at least 75 nm, at least 80 nm, or at least 85 nm. In certain embodiments, depth D1 is at most 1 nm, such as at most 2 nm, at most 3 nm, at most 4 nm, at most 5 nm, at most 6 nm, at most 7 nm, at most 8 nm, at most 9 nm, at most 10 nm, at most 12 nm, at most 14 nm, at most 16 nm, at most 18 nm, at most 20 nm, at most 22 nm, at most 25 nm, at most 30 nm, at most 35 nm, at most 40 nm, at most 45 nm, at most 50 nm, at most 55 nm, at most 60 nm, at most 65 nm, at most 70 nm, at most 75 nm, at most 80 nm, at most 85 nm or at most 90 nm.

As shown in FIG. 11A, each source/drain feature 321 has a lowest point or surface defining a horizontal bottom plane 3218 and an uppermost point or surface defining a horizontal upper plane 3219. Each source/drain feature 321 is formed with a height H1 from the horizontal bottom plane 3218 to the horizontal upper plane 3219.

In certain embodiments, height H1 is at least 1 nm, such as at least 2 nm, at least 3 nm, at least 4 nm, at least 5 nm, at least 6 nm, at least 7 nm, at least 8 nm, at least 9 nm, at least 10 nm, at least 12 nm, at least 14 nm, at least 16 nm, at least 18 nm, at least 20 nm, at least 25 nm, at least 30 nm, at least 35 nm, at least 40 nm, at least 45 nm, at least 50 nm, at least 55 nm, at least 60 nm, at least 65 nm, at least 70 nm, at least 75 nm, at least 80 nm, or at least 85 nm. In certain embodiments, height H1 is at most 1 nm, such as at most 2 nm, at most 3 nm, at most 4 nm, at most 5 nm, at most 6 nm, at most 7 nm, at most 8 nm, at most 9 nm, at most 10 nm, at most 12 nm, at most 14 nm, at most 16 nm, at most 18 nm, at most 20 nm, at most 22 nm, at most 25 nm, at most 30 nm, at most 35 nm, at most 40 nm, at most 45 nm, at most 50 nm, at most 55 nm, at most 60 nm, at most 65 nm, at most 70 nm, at most 75 nm, at most 80 nm, at most 85 nm or at most 90 nm.

In certain embodiments, the device may have a depth D1:height H1 ratio of at least 0.1:1, at least 0.2:1, at least 0.3:1, at least 0.4:1, at least 0.5:1, at least 0.6:1, at least 0.7:1, at least 0.8:1, at least 0.9:1, at least 1.0:1, at least 1.1:1, at least 1.2:1, at least 1.3:1, at least 1.4:1, at least 1.5:1, at least 1.6:1, at least 1.7:1, at least 1.8:1, at least 1.9:1, or at least 2.0:1.

In certain embodiments, the device may have a depth D1:height H1 ratio of at most 0.1:1, at most 0.2:1, at most 0.3:1, at most 0.4:1, at most 0.5:1, at most 0.6:1, at most 0.7:1, at most 0.8:1, at most 0.9:1, at most 1.0:1, at most 1.1:1, at most 1.2:1, at most 1.3:1, at most 1.4:1, at most 1.5:1, at most 1.6:1 at most 1.7:1, at most 1.8:1, at most 1.9:1, or at most 2.0:1.

In certain embodiments, the device may have a height H1:depth D1 ratio of at least 0.1:1, at least 0.2:1, at least 0.3:1, at least 0.4:1, at least 0.5:1, at least 0.6:1, at least 0.7:1, at least 0.8:1, at least 0.9:1, at least 1.0:1, at least 1.1:1, at least 1.2:1, at least 1.3:1, at least 1.4:1, at least 1.5:1, at least 1.6:1, at least 1.7:1, at least 1.8:1, at least 1.9:1, or at least 2.0:1.

In certain embodiments, the device may have a height H1:depth D1 ratio of at most 0.1:1, at most 0.2:1, at most 0.3:1, at most 0.4:1, at most 0.5:1, at most 0.6:1, at most 0.7:1, at most 0.8:1, at most 0.9:1, at most 1.0:1, at most 1.1:1, at most 1.2:1, at most 1.3:1, at most 1.4:1, at most 1.5:1 at most 1.6:1, at most 1.7:1, at most 1.8:1, at most 1.9:1, or at most 2.0:1.

The width of the CPODE insulation feature 1002, in the X-direction, may also affect the preset limit.

As shown in FIG. 11A, the CPODE insulation feature 1002 has a width W1 defined as the distance between its two opposite sides. In FIG. 11A, the width W1 may be measured at the bottom plane 1003 or at the upper plane 1004, or at a horizontal plane therebetween. Generally, increasing the width of the CPODE insulation feature 1002 may increase the punch-through voltage at which the TVS device 1100 becomes active.

In certain embodiments, width W1 is at least 1 nm, such as at least 2 nm, at least 3 nm, at least 4 nm, at least 5 nm, at least 6 nm, at least 7 nm, at least 8 nm, at least 9 nm, at least 10 nm, at least 12 nm, at least 14 nm, at least 16 nm, at least 18 nm, at least 20 nm, at least 25 nm, at least 30 nm, at least 35 nm, at least 40 nm, at least 45 nm, or at least 50 nm. In certain embodiments, width W1 is at most 1 nm, such as at most 2 nm, at most 3 nm, at most 4 nm, at most 5 nm, at most 6 nm, at most 7 nm, at most 8 nm, at most 9 nm, at most 10 nm, at most 12 nm, at most 14 nm, at most 16 nm, at most 18 nm, at most 20 nm, at most 22 nm, at most 25 nm, at most 30 nm, at most 35 nm, at most 40 nm, at most 45 nm, or at most 50 nm.

In certain embodiments, the device may have a depth D1:width W1 ratio of at least 0.1:1, at least 0.2:1, at least 0.3:1, at least 0.4:1, at least 0.5:1, at least 0.6:1, at least 0.7:1, at least 0.8:1, at least 0.9:1, at least 1.0:1, at least 1.1:1, at least 1.2:1, at least 1.3:1, at least 1.4:1, at least 1.5:1, at least 1.6:1, at least 1.7:1, at least 1.8:1, at least 1.9:1, at least 2.0:1, at least 2.5:1, at least 3.0:1, at least 3.5:1, at least 4.0:1, at least 4.5:1, or at least 5.0:1.

In certain embodiments, the device may have a depth D1:width W1 ratio of at most 0.1:1, at most 0.2:1, at most 0.3:1, at most 0.4:1, at most 0.5:1, at most 0.6:1, at most 0.7:1, at most 0.8:1, at most 0.9:1, at most 1.0:1, at most 1.1:1, at most 1.2:1, at most 1.3:1, at most 1.4:1, at most 1.5:1, at most 1.6:1 at most 1.7:1, at most 1.8:1, at most 1.9:1, at most 2.0:1, at most 2.5:1, at most 3.0:1, at most 3.5:1, at most 4.0:1, at most 4.5:1, or at most 5.0:1.

In certain embodiments, the device may have a width W1:depth D1 ratio of at least 0.05:1, at least 0.1:1, at least 0.2:1, at least 0.3:1, at least 0.4:1, at least 0.5:1, at least 0.6:1, at least 0.7:1, at least 0.8:1, at least 0.9:1, at least 1.0:1, at least 1.1:1, at least 1.2:1, at least 1.3:1, at least 1.4:1, at least 1.5:1, at least 1.6:1, at least 1.7:1, at least 1.8:1, at least 1.9:1, or at least 2.0:1.

In certain embodiments, the device may have a width W1: depth D1 ratio of at most 0.1:1, at most 0.2:1, at most 0.3:1, at most 0.4:1, at most 0.5:1, at most 0.6:1, at most 0.7:1, at most 0.8:1, at most 0.9:1, at most 1.0:1, at most 1.1:1, at most 1.2:1, at most 1.3:1, at most 1.4:1, at most 1.5:1 at most 1.6:1, at most 1.7:1, at most 1.8:1, at most 1.9:1, or at most 2.0:1.

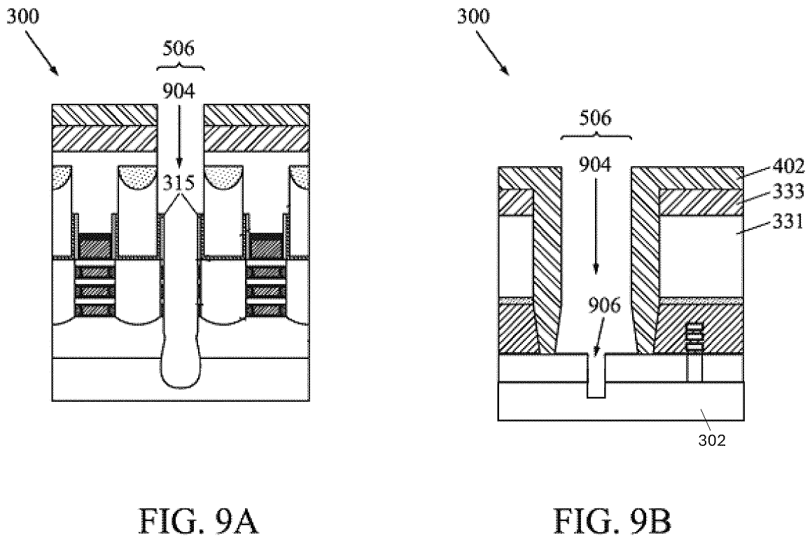

FIG. 13 presents a similar view to FIG. 11A, of another structure of a CPODE insulation feature 1002, fabricated in accordance with method 200. In FIG. 13, the insulation feature 1002 is formed with a depth D2 greater than depth D1. Further, the insulation feature 1002 is formed with a tapered bottom end, such that the width D2 may be measured at the upper plane 1004 or at a plane defined by the source/drain regions 321.

In each embodiment of FIG. 11A. 11B, and 11C and 13, the source/drain regions 321 have a first dopant type and the surrounding region of the fin 104 and substrate 302 have a second dopant type. For example, the source/drain regions may be doped with an n-type dopant and the surrounding region of the fin 104 and substrate 302 may be doped with a p-type dopant. In other embodiments, the source/drain regions may be doped with a p-type dopant and the surrounding region of the fin 104 and substrate 302 may be doped with an n-type dopant.

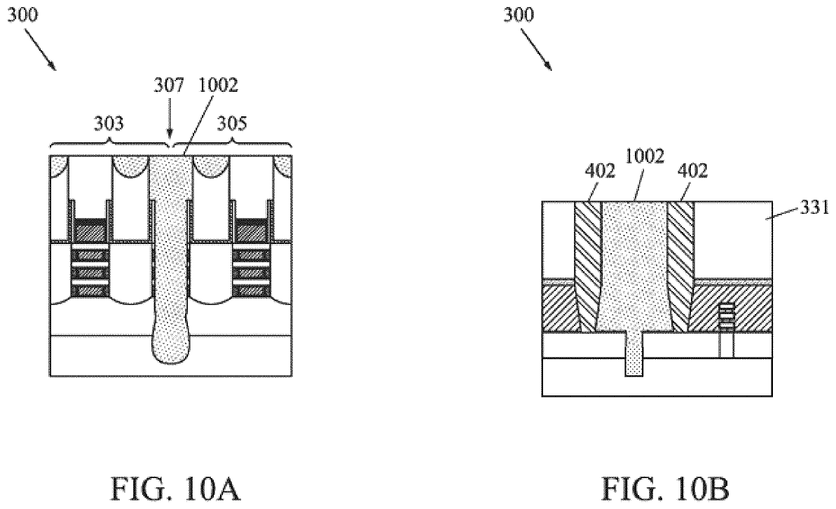

FIGS. 14 and 15 present similar views to FIGS. 11A and 13 and illustrate electrical behavior of the TVS device 1100 during operation of the functional circuit 1200.

In FIG. 14, a first N/P junction 1401 is defined under the first source/drain feature 3211 and a second N/P junction 1402 is defined under the second source/drain feature 3212. FIG. 14 illustrates that, in the normal range of the signal working voltage applied to functional circuit 1200, each junction 1401 and 1402 intersects the CPODE insulation feature 1002. As a result, there is no current path between the source/drain regions 3211 and 3212.

In FIG. 15, a punch-through voltage (Vin) is applied at node 912. The punch-through voltage is greater than the normal range of the signal working voltage. As a result, the first N/P junction 1401 and second N/P junction 1402 come into contact with one another. As a result, a current path between the source/drain regions 3211 and 3212 and under the CPODE insulation feature 1002 is formed.

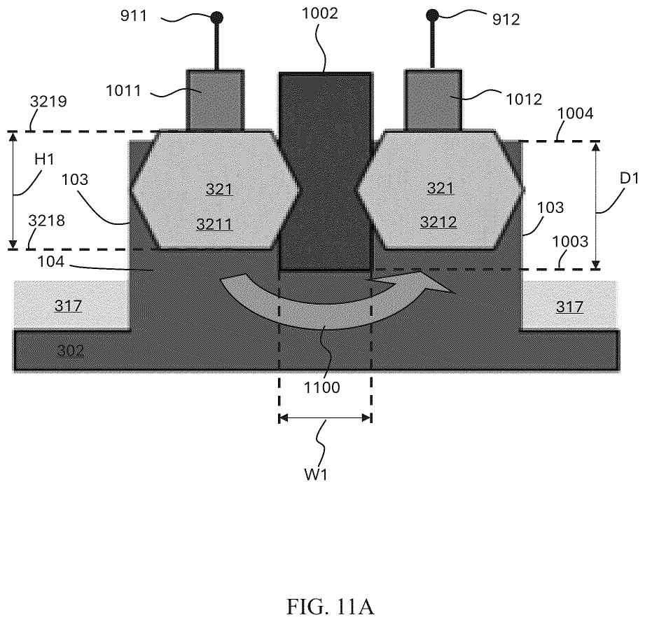

FIG. 16 is a current-voltage graph of the TVS device 1100, with current (I) on the vertical axis and voltage (V) as the horizontal axis. As shown, no current passes through the TVS device 1100 at voltages lower than the punch-through voltage Vp. At punch-through voltage Vp, the TVS device 1100 is turned on and the current passes through the TVS device 1100. Thus, no voltage greater than the punch-through voltage Vp may be applied to the protected functional circuit 1200.

It is noted that in the above embodiments, the CPODE insulation features 1002 extends deeper than the source/drain features 321, i.e., plane 1003 is located below the source/drain regions 321 and does not pass through the source/drain features 321. In such embodiments, the CPODE insulation feature 1002 is used for modulating the maximum voltage. In other words, the TVS device 1100 is a V_max modulator.

While FIGS. 9A and 10A illustrate an embodiment in which all of the semiconductor nanosheet channel layers 306 are removed during the CPODE etching process of block 214, other embodiments are envisioned.

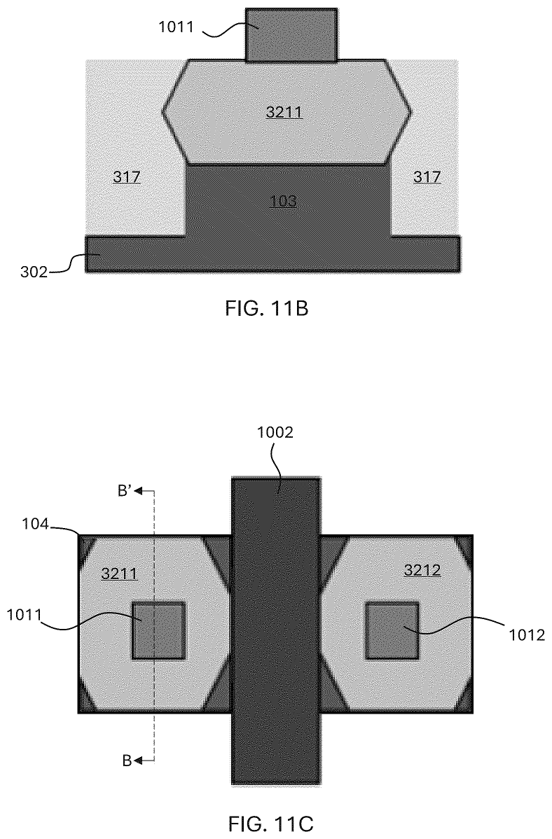

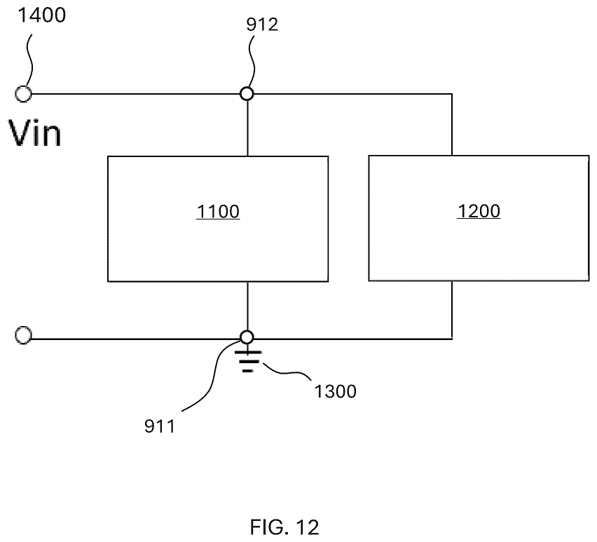

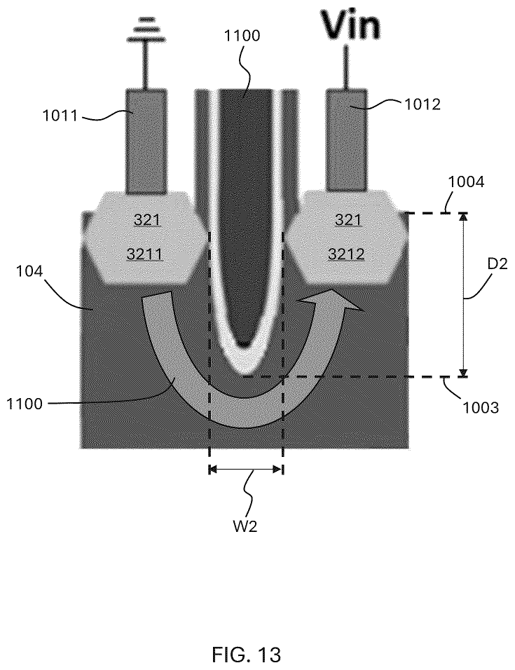

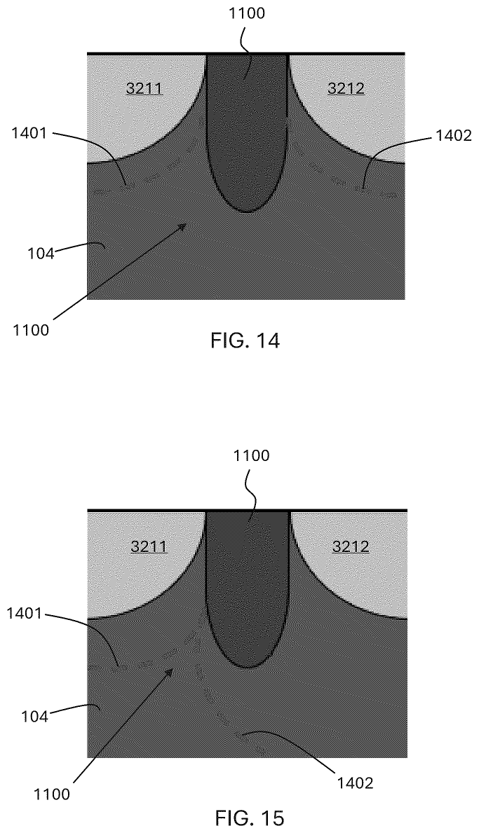

For example, FIGS. 17A, 17B, and 17C illustrate that the CPODE etching process of block 214 may only etch partially through upper semiconductor nanosheet channel layers 306 while lower semiconductor nanosheet channel layers 306 remain. Thus, the CPODE insulation feature 1002 is then formed over the remaining semiconductor nanosheet channel layers 306.

FIG. 17A is a cross-sectional schematic similar to FIG. 11A. FIG. 17B is a cross-sectional view similar to FIG. 11B. FIG. 17C is an overhead schematic.

As shown in FIGS. 17A, 17B, and 17C, forming circuits at block 220 includes forming a first source/drain contact 1011 electrically connected to the first source/drain feature 3211, and forming a second source/drain contact 1012 electrically connected to the second source/drain feature 3212. As further shown, the first source/drain contact 1011 is electrically connected to a first node 911 and the second source/drain contact 1012 is electrically connected to a second node 912.

A transient voltage suppressor (TVS) device in the form of a shunt path 1100 is formed between the first source/drain feature 3211 and the second source/drain feature 3212. The shunt path 1100 extends through the fin element 104 and/or substrate 302 and under the CPODE insulation feature 1002. More specifically, the TVS device 1100 may be located in the remaining semiconductor nanosheet channel layers 306.

As shown in FIG. 17A, the CPODE insulation feature 1002 has a lowest point or surface defining a horizontal bottom plane 1003. Further, the fin element 104 has an uppermost point or surface defining a horizontal upper plane 1004. In the embodiment of FIGS. 17A-17C, the upper plane 1004 is defined by the uppermost remaining portions of semiconductor nanosheet channel layers 306.

The CPODE insulation feature 1002 is formed with a depth D3 from the upper surface plane 1004 to the horizontal bottom plane 1003. As shown, in the embodiment of FIG. 17A, the bottom plane 1003 passes through the source/drain features 321, i.e., the CPODE insulation feature 1002 does not extend as deep as the source/drain features 321.

As shown in FIG. 17A, the CPODE insulation feature 1002 has a width W3 defined as the distance between its two opposite sides. In FIG. 11A, the width W3 may be measured at the bottom plane 1003 or at the upper plane 1004, or at a horizontal plane therebetween. Generally, increasing the width of the CPODE insulation feature 1002 may increase the punch-through voltage at which the TVS device 1100 becomes active.

FIG. 17D illustrates an alternative structure to the embodiment of FIG. 17A. In FIG. 17D, the CPODE insulation feature 1002 is formed with a depth D4 from the upper surface plane 1004 to the horizontal bottom plane 1003. As shown, in the embodiment of FIG. 17D, the bottom plane 1003 passes through the source/drain features 321, i.e., the CPODE insulation feature 1002 does not extend as deep as the source/drain features 321.

In each embodiment of FIG. 17A. 17B, 17C, and 17D, the source/drain regions 321 have a first dopant type and the surrounding region of the fin 104 and substrate 302 have a second dopant type. For example, the source/drain regions may be doped with an n-type dopant and the surrounding region of the fin 104 and substrate 302 may be doped with a p-type dopant. In other embodiments, the source/drain regions may be doped with a p-type dopant and the surrounding region of the fin 104 and substrate 302 may be doped with an n-type dopant.

It is noted that in the above embodiments, the source/drain features 321 extend deeper than the CPODE insulation features 1002, i.e., plane 1003 passes through the source/drain features 321. In such embodiments, the CPODE insulation feature 1002 is used for modulating the maximum current. In other words, the TVS device 1100 is an I_max modulator.

While previous devices 300 have been described in relation to a single source/drain contact 1011 formed in contact with a single source/drain feature 3211 and a single source/drain contact 1012 formed in contact with a single source/drain feature 3212 over a single fin element 104, other embodiments are envisioned.

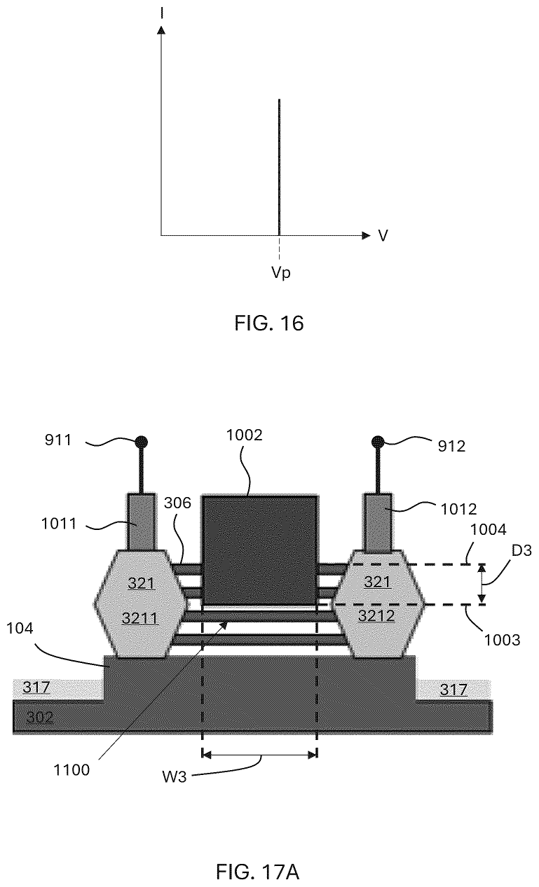

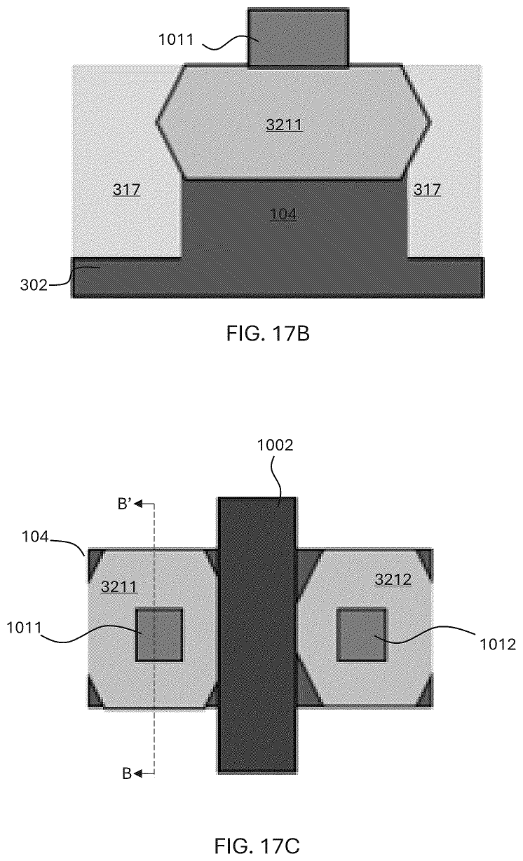

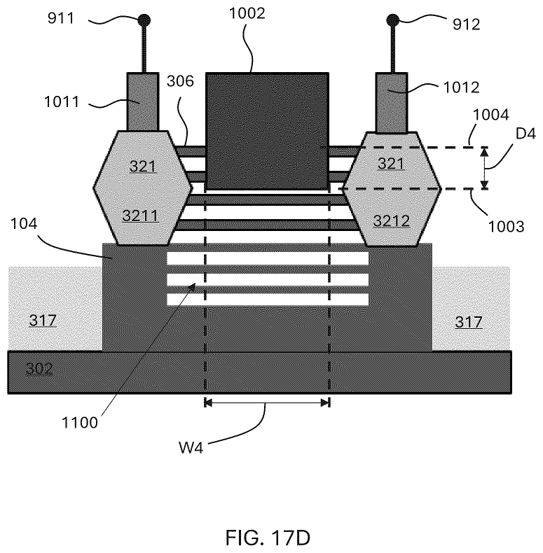

For example, FIGS. 18A, 18B, and 18C illustrate an embodiment in which a single source/drain contact 1011 is formed in connection with a source/drain feature 3211 formed in a first fin 1041 and in connection with a source/drain feature 3213 formed in a second fin 1042. Further, a single source/drain contact 1012 is formed in connection with a source/drain feature 3212 formed in a first fin 1041 and in connection with a source/drain feature 3214 formed in a second fin 1042.

Specifically, in the embodiment of FIGS. 18A, 18B, and 18C, adjacent fins 1041 and 1042 are processed according to the method 200. When epitaxially growing material to form the source/drain features 321, the material merges. Then, when forming the source/drain contacts 1011 and 1012, each contact 1011 and 1012 are contacted to the merged source/drain features.

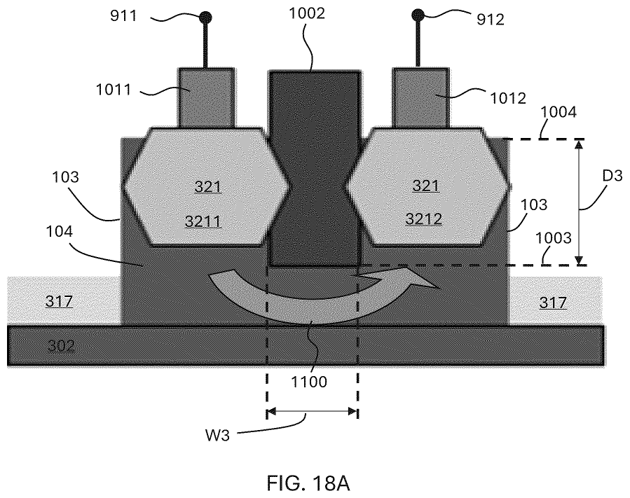

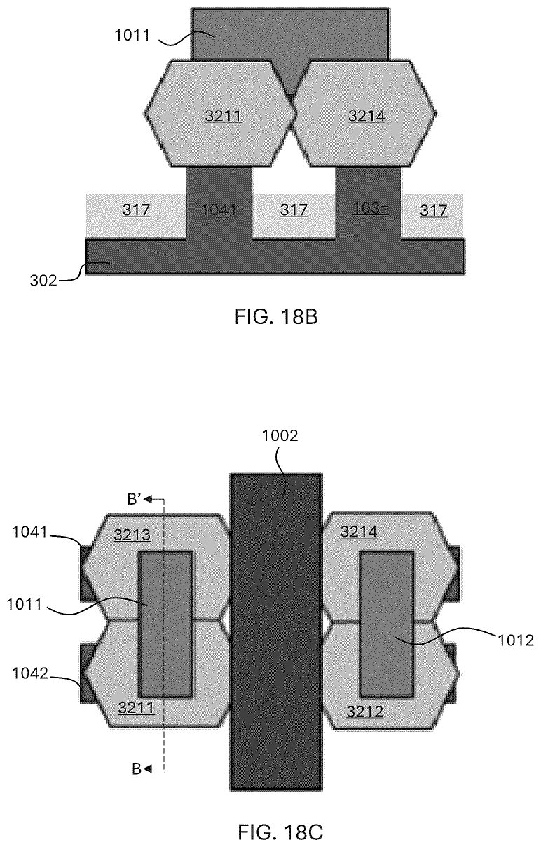

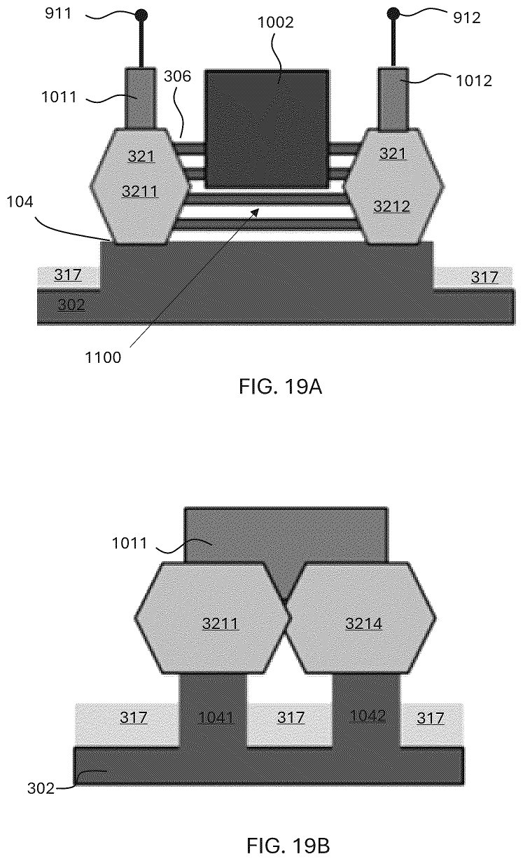

While FIGS. 18A, 18B, and 18C may illustrate a FinFET device 300, FIGS. 19A, 19B, and 19C illustrate a similar embodiment for a GAA device 300. Specifically, a single source/drain contact 1011 is formed in connection with a source/drain feature 3211 formed in a first fin 1041 and in connection with a source/drain feature 3213 formed in a second fin 1042. Further, a single source/drain contact 1012 is formed in connection with a source/drain feature 3212 formed in a first fin 1041 and in connection with a source/drain feature 3214 formed in a second fin 1042.

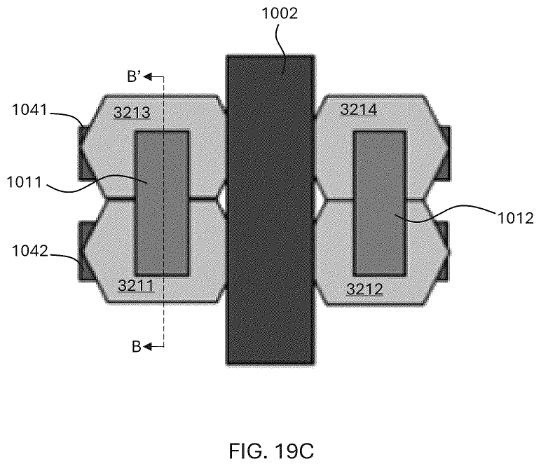

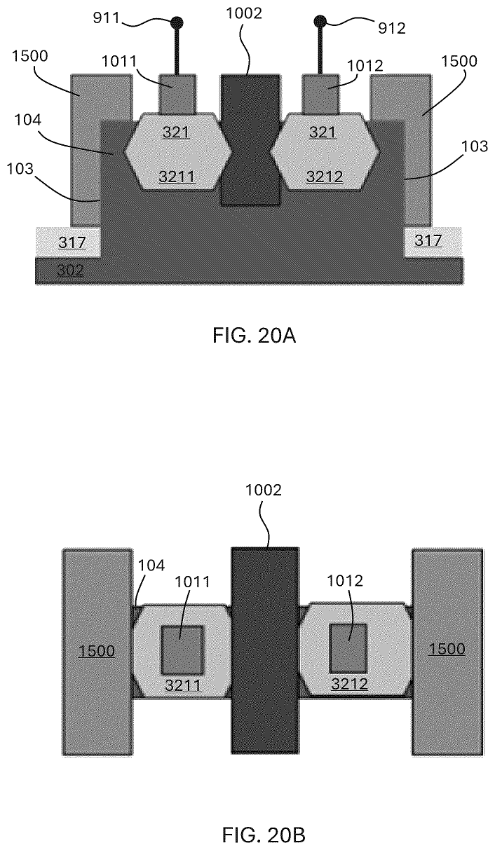

FIGS. 20A and 20B illustrate an embodiment in which poly over diffusion edge PODE insulation structures 1500 are formed at the ends 103 of the fin element 104 to further isolate the fin element 104. FIG. 20A is a cross-sectional schematic similar to FIG. 11A. FIG. 20B is an overhead schematic of the device of FIG. 20A. The PODE structures 1500 may be formed during the CPODE formation process of method 200. As shown, the PODE structures 1500 are formed around the ends 103 of the fin element 104. Thus, the fin element 104 is not etched to form a trench in which the PODE structures 150 are formed. Further, the PODE structures 1500 may be formed over the STI features 317.

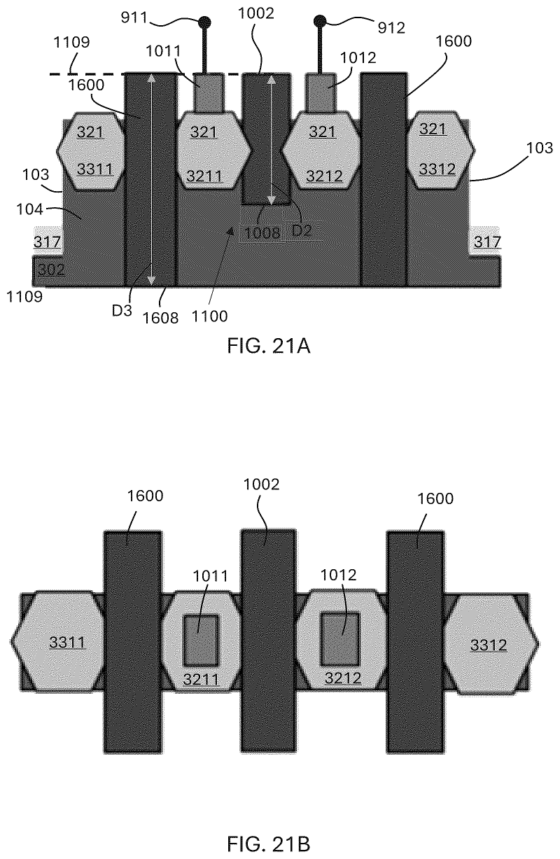

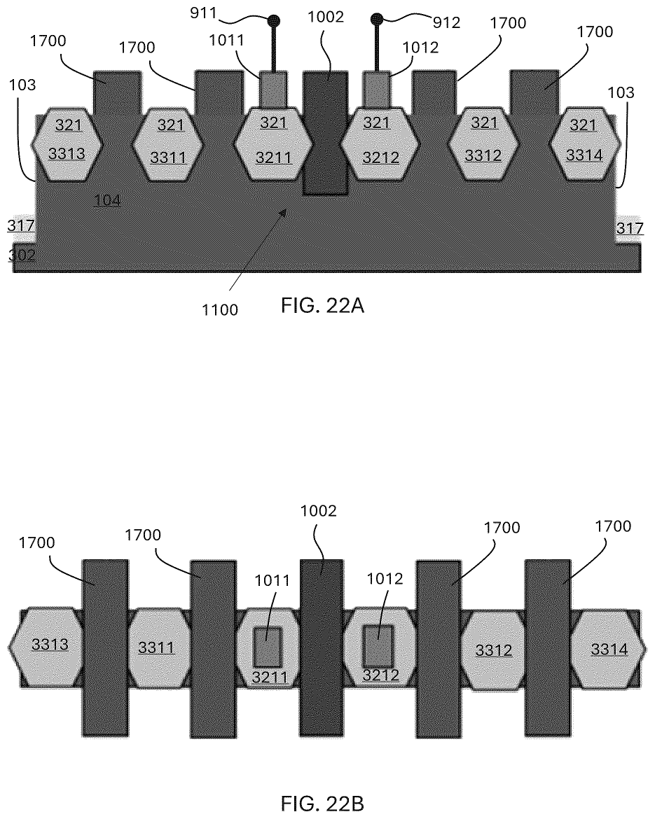

FIGS. 21A and 21B illustrate another embodiment. FIG. 21A is a cross-sectional schematic similar to FIG. 11A. FIG. 21B is an overhead schematic of the device of FIG. 21A.

In the embodiment of FIGS. 21A and 21B, multiple CPODE insulation features are formed. Specifically, method 200 may be performed to form three dummy gate structures 313. Then, the method 200 continues with removing all three dummy gate structures 313 and forming the CPODE insulation features. As shown in FIG. 21A, the central CPODE insulation feature 1002 is located between the source/drain features 3211 and 3212 and forms the TVS device 1100.

The adjacent CPODE insulation features 1600 are formed, respectively, between the source/drain feature 3211 and adjacent source/drain feature 3311 and between the source/drain feature 3212 and adjacent source/drain feature 3312. As shown, the CPODE insulation features 1600 extend to a greater depth such as into the substrate 302 at a depth below the STI regions 317. As a result, the portion of the fin element 104 between the CPODE insulation features 1600 and under the CPODE insulation feature 1002 is insulated from neighboring semiconductor regions.

More specifically, in FIG. 21A, the structure has a horizontal uppermost plane 1109 which may be defined by uppermost surfaces of the CPODE insulation feature 1002 and adjacent CPODE insulation features 1600. The central CPODE insulation feature 1002 has a lowest surface defining a horizontal plane 1008, and the central CPODE insulation feature 1002 extends to a depth D2 from the plane 1109 to the plane 1008. Likewise, each adjacent CPODE insulation feature 1600 has a lowest surface defining a horizontal plane 1608, and each adjacent CPODE insulation feature 1600 extends to a depth D3 from the plane 1109 to the plane 1608.

In certain embodiments, the device may have a depth D2:depth D3 ratio of at least 0.1:1, at least 0.2:1, at least 0.3:1, at least 0.4:1, at least 0.5:1, at least 0.6:1, at least 0.7:1, at least 0.8:1, at least 0.9:1, or at least 0.95:1.

In certain embodiments, the device may have a depth D2:depth D3 ratio of at most at most 0.2:1, at most 0.3:1, at most 0.4:1, at most 0.5:1, at most 0.6:1, at most 0.7:1, at most 0.8:1, at most 0.9:1, or at most 0.95:1.

In certain embodiments, the device may have a depth D3:depth D2 ratio of at least 1.05:1, at least 1.1:1, at least 1.2:1, at least 1.3:1, at least 1.4:1, at least 1.5:1, at least 1.6:1, at least 1.7:1, at least 1.8:1, at least 1.9:1, at least 2.0:1, at least 2.1:1, at least 2.2:1, at least 2.3:1, at least 2.4:1, or at least 2.5:1.

In certain embodiments, the device may have a depth D3:depth D2 ratio of at most 1.05:1, at most 1.1:1, at most 1.2:1, at most 1.3:1, at most 1.4:1, at most 1.5:1, at most 1.6:1, at most 1.7:1, at most 1.8:1, at most 1.9:1, at most 2.0:1, at most 2.1:1, at most 2.2:1, at most 2.3:1, at most 2.4:1, or at most 2.5:1.

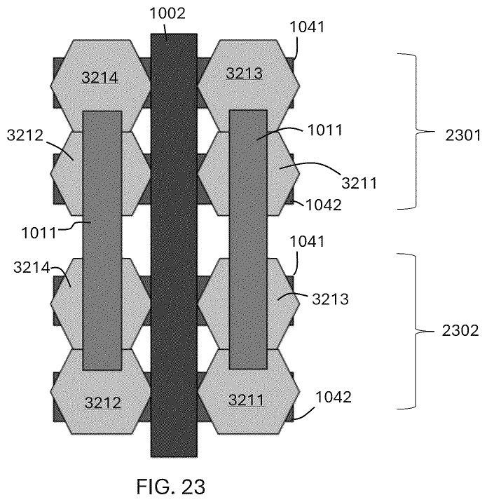

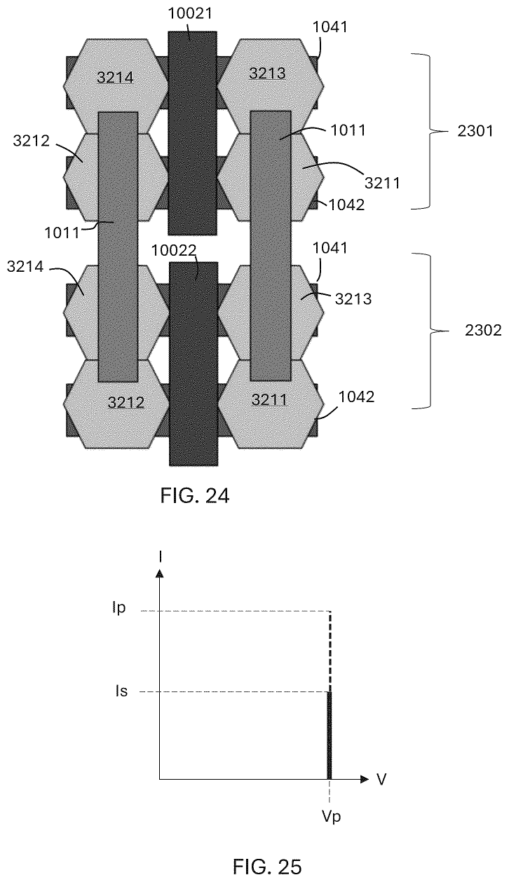

FIGS. 22A and 22B illustrate another embodiment. FIG. 22A is a cross-sectional schematic similar to FIG. 11A. FIG. 22B is an overhead schematic of the device of FIG. 22A.

In the embodiment of FIGS. 22A and 22B, floating dummy gates 1700 may provide for insulation. For example, at block 202 of method 200, floating dummy gates 1700 are formed over the fin element 104. For example, floating dummy gates 1700 are formed between, respectively, adjacent source/drain features 3313 and 3311, adjacent source/drain feature 3311 and source/drain feature 3211, source/drain feature 3212 and adjacent source/drain feature 3312, and adjacent source/drain features 3312 and 3314.

After formation of the CPODE insulation feature 1002, the floating dummy gates 1700 are located between the CPODE insulation feature 1002 and the ends 103 of the fin element 104.

Embodiments herein further provide for various layouts of CPODE insulation features 1002 for forming TVS devices 1100 according to method 200.

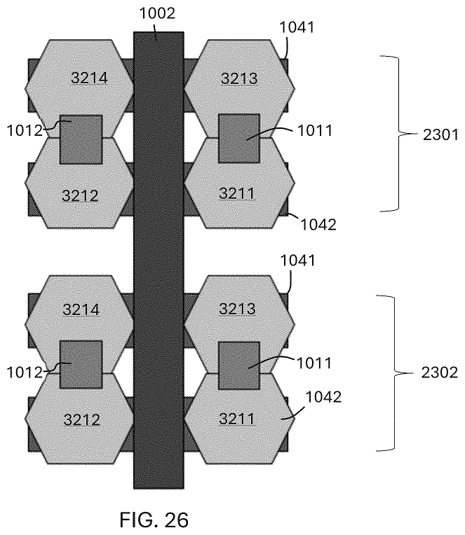

FIG. 23 is an overhead schematic of a device 300 formed according to the description above. In FIG. 23, a first pair 2301 of fin elements 1041 and 1042 and a second pair 2302 of fin elements 1041 and 1042 are formed. Source/drain features 3211 and 3213 are formed and merged in each pair 2301 and 2302. Likewise, source/drain features 3212 and 3214 are formed and merged in each pair 2301 and 2302.

As shown, a single CPODE insulation feature 1002 extends across each pair 2301 and 2031 of fin elements 1041 and 1042. Further, in each pair 2301 and 2302, the CPODE insulation feature 1002 separates the merged source/drain features 3211/3213 from the merged source/drain features 3212/3214.

Further, a single first source/drain contact 1011 is contacted to the merged source/drain features 3211/3213 of each pair 2301 and 2302 and a single second source/drain contact 1012 is contacted to the merged source/drain features 3212/3214 of each pair 2301 and 2302. In other words, each source/drain contact 1011 and 1012 extends across both pairs 2301 and 2301. Thus, the device 300 includes two contacts 1011 and 1012.

As described above, contacts 1011 and 1012 are arranged in electrical communication to form two parallel TVS devices that are in parallel to a functional circuit.

It is noted that the CPODE insulation feature of FIG. 23 has a same constant depth, length, and width.

FIG. 24 is an overhead schematic of a device 300, similar to the device of FIG. 23, formed according to the description above. In FIG. 24, a first pair 2301 of fin elements 1041 and 1042 and a second pair 2302 of fin elements 1041 and 1042 are formed. Source/drain features 3211 and 3213 are formed and merged in each pair 2301 and 2302. Likewise, source/drain features 3212 and 3214 are formed and merged in each pair 2301 and 2302.

As shown, a first CPODE insulation feature 10021 extends across the pair 2301 of fin elements 1041 and 1042 and a second CPODE insulation feature 10022 extends across the pair 2302 of fin elements 1041 and 1042. Further, in each pair 2301 and 2302, the CPODE insulation feature 1002 separates the merged source/drain features 3211/3213 from the merged source/drain features 3212/3214.

Further, a first source/drain contact 1011 is contacted to the merged source/drain features 3211/3213 of each pair 2301 and 2302 and a second source/drain contact 1012 is contacted to the merged source/drain features 3212/3214 of each pair 2301 and 2302.

As described above, contacts 1011 and 1012 are arranged in electrical communication to form a TVS device in parallel to a functional circuit.

It is noted that the CPODE insulation features 10021 and 10022 of FIG. 24 have a same constant depth and width.

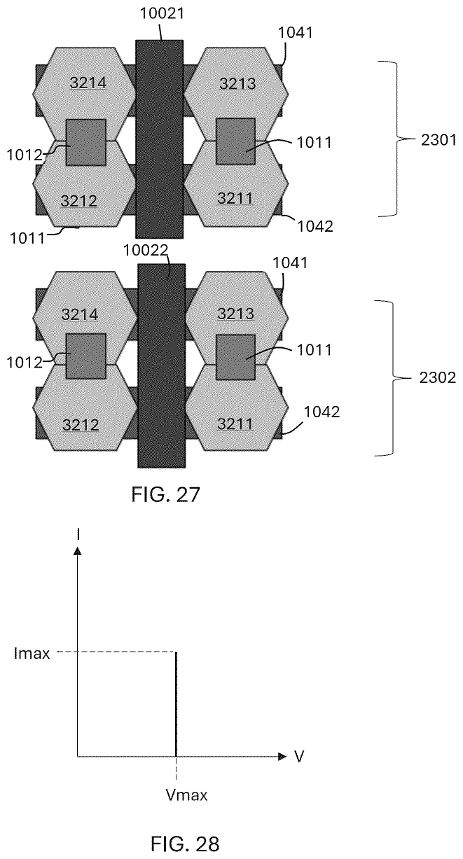

FIG. 25 is a current-voltage graph for the devices 300 of FIGS. 23 and 24. In the embodiments of FIGS. 23 and 24, two paralleled CPODE-based TVS devices are provided. The paralleled devices have a maximum voltage Ip that is greater than the maximum voltage Is for a single CPODE-based TVS device of the same structure. In certain embodiments, Ip is twice Is.

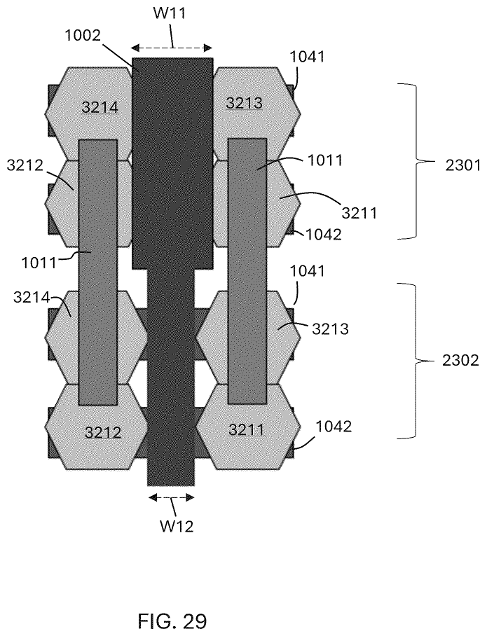

FIG. 26 is an overhead schematic of a device 300, similar to the device of FIG. 23, formed according to the description above. In FIG. 26, a first pair 2301 of fin elements 1041 and 1042 and a second pair 2302 of fin elements 1041 and 1042 are formed. Source/drain features 3211 and 3213 are formed and merged in each pair 2301 and 2302. Likewise, source/drain features 3212 and 3214 are formed and merged in each pair 2301 and 2302.

As shown, a single CPODE insulation feature 1002 extends across each pair 2301 and 2031 of fin elements 1041 and 1042. Further, in each pair 2301 and 2302, the CPODE insulation feature 1002 separates the merged source/drain features 3211/3213 from the merged source/drain features 3212/3214.

In the embodiment of FIG. 26, a first source/drain contact 1011 is contacted to the merged source/drain features 3211/3213 of each pair 2301 and 2302 and a second source/drain contact 1012 is contacted to the merged source/drain features 3212/3214 of each pair 2301 and 2302. In other words, each pair 2301 and 2302 is provided with a source/drain contact 1011 and a source/drain contact 1012. Thus, the device 300 includes two contacts 1011 and two contacts 1012.

As described above, contacts 1011 and 1012 are arranged in electrical communication to form a TVS device in parallel to a functional circuit.

It is noted that the CPODE insulation feature of FIG. 23 has a same constant depth, length, and width.

FIG. 27 is an overhead schematic of a device 300, similar to the device of FIG. 24, formed according to the description above. In FIG. 27, a first pair 2301 of fin elements 1041 and 1042 and a second pair 2302 of fin elements 1041 and 1042 are formed. Source/drain features 3211 and 3213 are formed and merged in each pair 2301 and 2302. Likewise, source/drain features 3212 and 3214 are formed and merged in each pair 2301 and 2302.

As shown, a first CPODE insulation feature 10021 extends across the pair 2301 of fin elements 1041 and 1042 and a second CPODE insulation feature 10022 extends across the pair 2302 of fin elements 1041 and 1042. Further, in each pair 2301 and 2302, the CPODE insulation feature 1002 separates the merged source/drain features 3211/3213 from the merged source/drain features 3212/3214.

In the embodiment of FIG. 27, a first source/drain contact 1011 is contacted to the merged source/drain features 3211/3213 of each pair 2301 and 2302 and a second source/drain contact 1012 is contacted to the merged source/drain features 3212/3214 of each pair 2301 and 2302. In other words, each pair 2301 and 2302 is provided with a source/drain contact 1011 and a source/drain contact 1012. Thus, the device 300 includes two contacts 1011 and two contacts 1012.

As described above, contacts 1011 and 1012 are arranged in electrical communication to form a TVS device in parallel to a functional circuit.

It is noted that the CPODE insulation features 10021 and 10022 of FIG. 24 have a same constant depth and width.

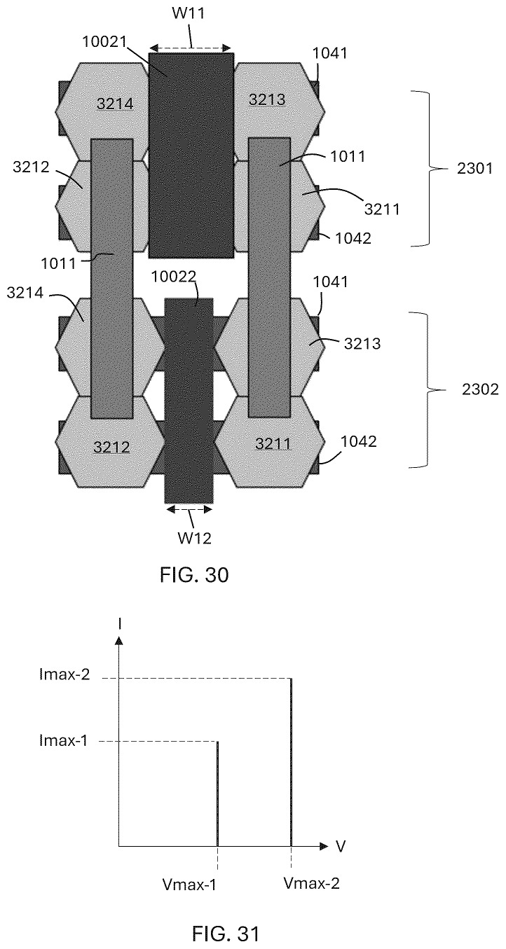

FIG. 28 is a current-voltage graph for the devices 300 of FIGS. 26 and 27. In the embodiments of FIGS. 26 and 27, the terminals of the paralleled CPODE-based TVS devices of FIGS. 24 and 25 are separated to form independent devices. Thus, the CPODE-based TVS devices in FIGS. 26 and 27, are independent but have the same maximum voltage Imax, as shown.

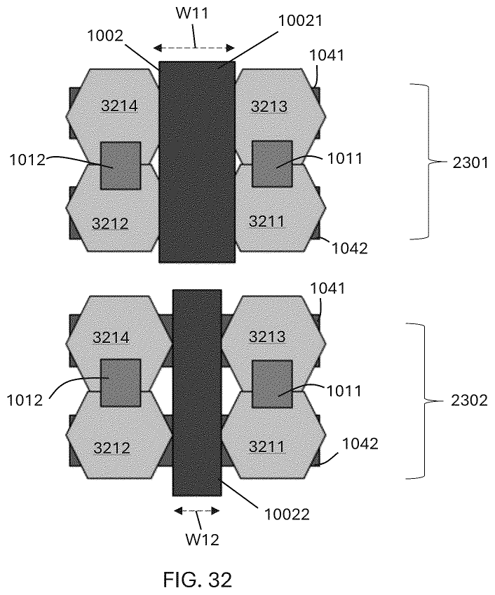

FIG. 29 is an overhead schematic of a device 300, similar to the device of FIG. 23, formed according to the description above. In FIG. 29, a single CPODE insulation feature 1002 extends across each pair 2301 and 2031 of fin elements 1041 and 1042. Further, in each pair 2301 and 2302, the CPODE insulation feature 1002 separates the merged source/drain features 3211/3213 from the merged source/drain features 3212/3214.

In FIG. 29, the CPODE insulation feature 1002 may have a same constant depth, or may be formed with different depths in different regions. As shown, the CPODE insulation feature 1002 has a width W11 in the region of pair 2301. Further, the CPODE insulation feature 1002 has a width W12 in the region of pair 2302. As shown, width W11 is greater than width W12.

In certain embodiments, the device may have a width W11:width W12 ratio of at least 1.05:1, at least 1.1:1, at least 1.2:1, at least 1.3:1, at least 1.4:1, at least 1.5:1, at least 1.6:1, at least 1.7:1, at least 1.8:1, at least 1.9:1, at least 2.0:1, at least 2.5:1, at least 3.0:1, at least 3.5:1, or at least 4.0:1.

In certain embodiments, the device may have a width W11:width W12 ratio of at most 1.05:1, at most 1.1:1, at most 1.2:1, at most 1.3:1, at most 1.4:1, at most 1.5:1, at most 1.6:1 at most 1.7:1, at most 1.8:1, at most 1.9:1, at most 2.0:1, at most 2.5:1, at most 3.0:1, at most 3.5:1, at most 4.0:1, or at most 5.0:1.

In certain embodiments, the device may have a width W12:width W11 ratio of at least 0.1:1, at least 0.2:1, at least 0.3:1, at least 0.4:1, at least 0.5:1, at least 0.6:1, at least 0.7:1, at least 0.8:1, at least 0.9:1, or at least 0.95:1.

In certain embodiments, the device may have a width W12:width W11 ratio of at most 0.1:1, at most 0.2:1, at most 0.3:1, at most 0.4:1, at most 0.5:1, at most 0.6:1, at most 0.7:1, at most 0.8:1, at most 0.9:1, or at most 0.95:1.

Thus, FIG. 29 illustrates that a CPODE insulation feature 1002 may be formed with different dimensions, such as different widths (and/or different depths), in different regions of the device 100. Thus, TVS devices having different punch-through voltages may be formed by a same CPODE insulation feature 1002.

FIG. 30 is an overhead schematic of a device 300, similar to the device of FIG. 24, formed according to the description above. In FIG. 30, a first CPODE insulation feature 10021 extends across the pair 2301 of fin elements 1041 and 1042 and a second CPODE insulation feature 10022 extends across the pair 2302 of fin elements 1041 and 1042. Further, in each pair 2301 and 2302, the CPODE insulation feature 1002 separates the merged source/drain features 3211/3213 from the merged source/drain features 3212/3214.

In FIG. 30, the first CPODE insulation feature 10021 and the second CPODE insulation feature 10022 have a same depth or different depths. As shown, the first CPODE insulation feature 10021 has a width W11. Further, the second CPODE insulation feature 10022 has a width W12. As shown, width W11 is greater than width W12. Thus, FIG. 30 illustrates that two CPODE insulation features 10021 and 10022 may be formed with different dimensions, such as different widths (and/or different depths), in different regions of the device 100. Thus, TVS devices having different punch-through voltages may be formed by two CPODE insulation features 10021 and 10022.

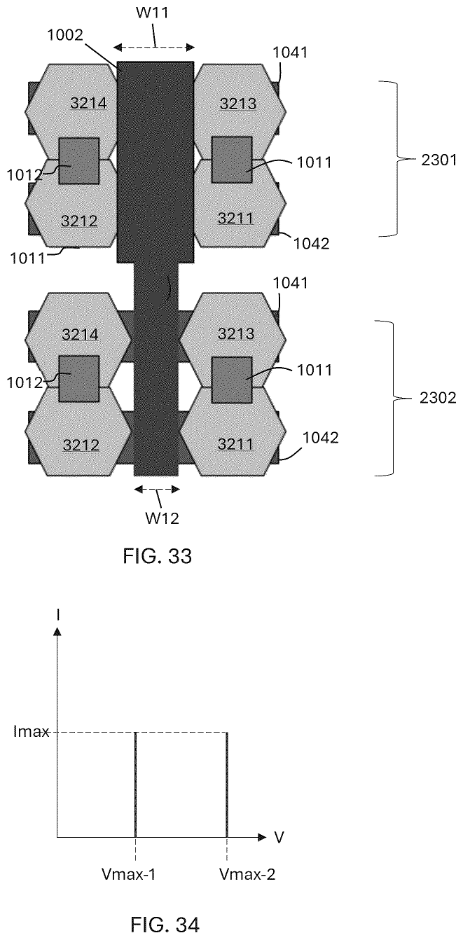

FIG. 31 is a current-voltage graph for the devices 300 of FIGS. 29 and 30.

The TVS device of FIG. 29 and FIG. 30 formed around the CPODE insulation feature 1002 or 10022, having the smaller width W2, has a smaller maximum voltage Vmax−1 and a smaller maximum current Imax−1. As arranged in parallel, the combination of CPODE-based TVS devices has a greater maximum voltage Vmax−2 and greater maximum current Imax−2.

Thus, forming CPODE insulation features with different selected dimensions provides a tunable maximum allowance transient voltage range.

FIG. 32 is an overhead schematic of a device 300, similar to the device of FIG. 26, formed according to the description above.

In FIG. 32, the CPODE insulation feature 1002 may have a same constant depth, or may be formed with different depths in different regions. As shown, the CPODE insulation feature 1002 has a width W11 in the region of pair 2301. Further, the CPODE insulation feature 1002 has a width W12 in the region of pair 2302. As shown, width W11 is greater than width W12. Thus, FIG. 32 illustrates that a CPODE insulation feature 1002 may be formed with different dimensions, such as different widths (and/or different depths), in different regions of the device 100. Thus, TVS devices having different punch-through voltages may be formed by a same CPODE insulation feature 1002.

FIG. 33 is an overhead schematic of a device 300, similar to the device of FIG. 27, formed according to the description above.

In FIG. 33, the first CPODE insulation feature 10021 and the second CPODE insulation feature 10022 have a same depth or different depths. As shown, the first CPODE insulation feature 10021 has a width W11. Further, the second CPODE insulation feature 10022 has a width W12. As shown, width W11 is greater than width W12. Thus, FIG. 33 illustrates that two CPODE insulation features 10021 and 10022 may be formed with different dimensions, such as different widths (and/or different depths), in different regions of the device 100. Thus, TVS devices having different punch-through voltages may be formed by two CPODE insulation features 10021 and 10022.

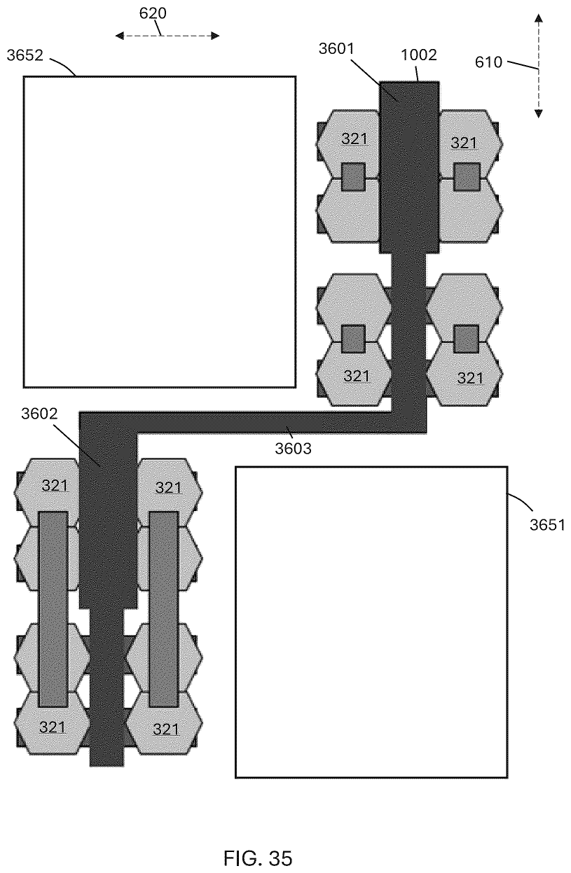

FIG. 34 is a current-voltage graph for the devices 300 of FIGS. 29 and 30. In the embodiments of FIGS. 32 and 33, the terminals of the paralleled CPODE-based TVS devices are separated to form independent devices. Thus, the CPODE-based TVS devices in FIGS. 32 and 33, are independent. Each CPODE-based TVS device has a same maximum current Imax. However, because the CPODE insulation features are formed with different dimensions, the CPODE-based TVS devices at 2301 and 2302, in both FIG. 32 and FIG. 33, have a different maximum voltage. Specifically, the CPODE-based TVS device formed with a CPODE insulation feature having a greater width W11 has a maximum voltage Vmax−2, and the CPODE-based TVS device formed with a CPODE insulation feature having a smaller width W12 has a maximum voltage Vmax−1 less than Vmax−2. This illustrates that several independent CPODE-based devices can be formed with different maximum allowance transient voltages.

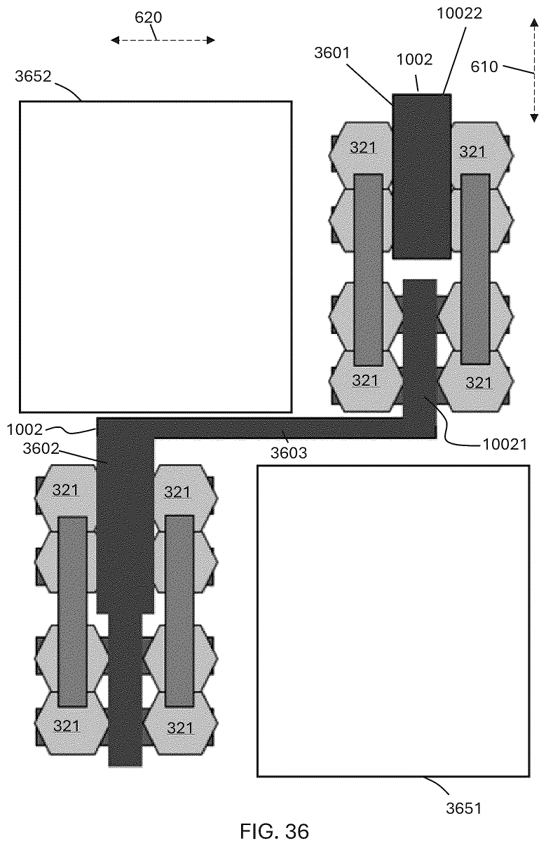

FIGS. 35 and 36 illustrate that CPODE insulation features 1002 need not be formed along a single linear direction, such as along the axis Y-Y′ of FIG. 1.

For example, in FIG. 35, a CPODE insulation feature 1002 is formed with a first insulation feature segment 3601 and a second insulation feature segment 3602 interconnected by a third insulation feature segment 3603.

The first insulation feature segment 3601 extends in a direction 610 and is located between source/drain features 321.

The second insulation feature segment 3602 extends in the direction 610, i.e., is parallel to the first insulation feature segment 3601. The second insulation feature segment 3602 is located between source/drain features 321.

The third insulation feature segment 3603 extends in a direction 620 between the first insulation feature segment 3601 and the second insulation feature segment 3602. In certain embodiments, direction 620 is perpendicular to direction 620.

The non-linear layout of the CPODE insulation feature 1002 allows for forming the CPODE-based TVS devices in regions that are not aligned in a linear direction. For example, a first circuit design region 3651 may lie adjacent to the first insulation feature segment 3601 in direction 610 and a second circuit design region 3652 may lie adjacent to the first insulation feature segment 3601 in direction 620, as shown.

In FIG. 35, an uninterrupted, single CPODE insulation feature 1002 includes each segment 3601, 3602, and 3063.

FIG. 36 illustrates an embodiment similar to FIG. 35, but in which the CPODE insulation feature 1002 includes an interruption. Specifically, segment 3601 is interrupted such that segment 3601 includes a CPODE insulation feature 10021 and a CPODE insulation feature 10022.

As shown in FIGS. 35 and 36, the CPODE-based devices may be formed with any of the features described above, including same or different CPODE insulation widths and depths, dedicated or shared source/drain contacts, or other features to provides the CPODE-based devices with desired properties.

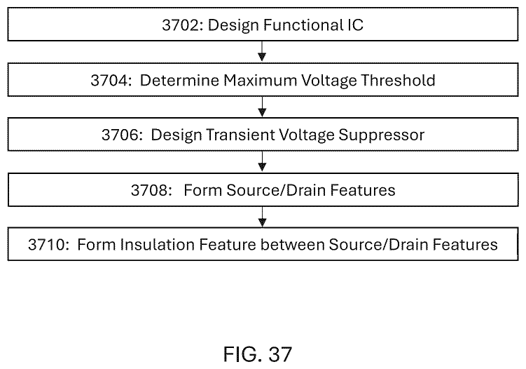

A method 3700 is illustrated in FIG. 37. Method 3700 includes, at block 3702, designing a functional integrated circuit in electrical communication with a first node and a second node. In certain embodiments, a plurality of functional integrated circuits are designed.

At block 3704, method 3700 includes determining a maximum voltage threshold for each functional integrated circuit.

At block 3706, method 3700 includes designing respective transient voltage suppressors as shunt paths between the first node and the second node of each circuit to discharge a current having a voltage exceeding the maximum voltage threshold, wherein each shunt path passes from a first source/drain feature to a second source/drain feature through a semiconductor material under a respective insulation feature having a selected width in a first direction and selected depth.

Method 3700 may continue at block 3708 with forming each first source/drain feature and second source/drain feature over the semiconductor material, wherein each respective first source/drain feature is distanced from the respective second source/drain feature in the first direction.

Method 3700 may continue at block 3710 with forming an insulation feature between each respective pair of first and second source/drain features with the respective selected width and the selected depth to define the respective shunt path.

Blocks 3708 and 3710 may incorporate blocks from method 200.

Thus various embodiments are described herein. In certain embodiments, two terminals are located about opposite sides of a CPODE structure, and are parallelly connected to a protected circuit. The CPODE dimension (length/width/depth) may be used for tuning maximum allowance transient voltage/current.

In certain embodiments, more than one CPODE-based TVS device may be paralleled to another one (or paralleled one) by a common (or different but with the same dimension) CPODE to increase allowance transient current.

In certain embodiments, the terminals of the parallel CPODE-based TVS devices are separated to form several independent CPODE-based TVS devices that have the same maximum allowance transient voltage.

In certain embodiments, the CPODE dimensions of parallel CPODE-based TVS devices may be different, which allows for forming a tunable allowance transient current (by the number of paralleled units) of each different allowance transient voltage range (by dimension of CPODE).

In certain embodiments, the CPODE dimensions of parallel CPODE-based TVS devices may be different to obtain desired maximum allowance transient voltages.

In certain embodiments, the CPODE shape may be vertical or other arbitrary shapes, like a Z-shape, that depends on the wafer layout.

In one embodiment herein, a method includes forming a first source/drain feature and a second source/drain feature over a substrate, wherein the first source/drain feature and the second source/drain feature are separated by a gate structure; removing the gate structure to form a trench; forming an insulation feature in the trench; and forming a functional circuit over the substrate, wherein a shunt path parallel to the functional circuit is defined under the insulation feature and between the first source/drain feature and the second source/drain feature.

In certain embodiments of the method, the first source/drain feature and the second source/drain feature define a first axis; the method further includes forming a third source/drain feature and a fourth source/drain feature separated by the gate structure; and the third source/drain feature and the fourth source/drain feature define a second axis parallel to the first axis.

In certain embodiments of the method, the shunt path is defined under the insulation feature, between the first source/drain feature and between the third source/drain feature and the fourth source/drain feature.

In certain embodiments of the method, the functional circuit is a first functional circuit; the method includes forming a second functional circuit over the substrate; and a second shunt path parallel to the second functional circuit is defined under the insulation feature and between the third source/drain feature and the fourth source/drain feature.

In another embodiment, a method includes designing a functional integrated circuit in electrical communication with a first node and a second node; determining a maximum voltage threshold or a maximum current threshold for the functional integrated circuit; designing a transient voltage suppressor as a shunt path between the first node and the second node to discharge a current exceeding the maximum current threshold and/or having a voltage exceeding the maximum voltage threshold, wherein the shunt path passes from a first source/drain feature to a second source/drain feature through a semiconductor material under an insulation feature having a selected width in a first direction and selected depth; forming the first source/drain feature and the second source/drain feature over the semiconductor material, wherein the first source/drain feature is distanced from the second source/drain feature in the first direction; and forming the insulation feature between the first source/drain feature and the second source/drain feature with the selected width and the selected depth to define the shunt path.

In certain embodiments of the method, the shunt path is a first shunt path passing from the first source/drain feature to the second source/drain feature; the transient voltage suppressor includes the first shunt path and a second shunt path between the first node and the second node, wherein the second shunt path passes from a third source/drain feature to a fourth source/drain feature through the semiconductor material under the insulation feature; the method further includes forming the third source/drain feature and the fourth source/drain feature over the semiconductor material, wherein the third source/drain feature is distanced from the fourth source/drain feature in the first direction; and forming the insulation feature includes forming the insulation feature between the third source/drain feature and the fourth source/drain feature.

In certain embodiments of the method, the functional integrated circuit is a first functional integrated circuit; the transient voltage suppressor is a first transient voltage suppressor; and the method further includes: designing a second functional integrated circuit in electrical communication with a third node and a fourth node; determining a second maximum voltage threshold for the second functional integrated circuit; designing a second transient voltage suppressor as a second shunt path between the third node and the fourth node to discharge a second current having a second voltage exceeding the second maximum voltage threshold, wherein the second shunt path passes from a third source/drain feature to a fourth source/drain feature through the semiconductor material under the insulation feature having a selected width in a first direction and selected depth; forming the third source/drain feature and the fourth source/drain feature over the semiconductor material, wherein the third source/drain feature is distanced from the fourth source/drain feature in the first direction; and forming the insulation feature between the third source/drain feature and the fourth source/drain feature with a second selected width and a second selected depth to define the second shunt path.

In certain embodiments of the method, the insulation feature includes a first segment between the first source/drain feature and the second source/drain feature; the functional integrated circuit is a first functional integrated circuit; the transient voltage suppressor is a first transient voltage suppressor; and the method further includes: designing a second functional integrated circuit in electrical communication with a third node and a fourth node; determining a second maximum voltage threshold for the second functional integrated circuit; designing a second transient voltage suppressor as a second shunt path between the third node and the fourth node to discharge a second current having a second voltage exceeding the second maximum voltage threshold, wherein the second shunt path passes from a third source/drain feature to a fourth source/drain feature through the semiconductor material under a second segment of the insulation feature having a second selected width in the first direction and second selected depth; forming the third source/drain feature and the fourth source/drain feature over the semiconductor material, wherein the third source/drain feature is distanced from the fourth source/drain feature in the first direction; and forming the second segment of the insulation feature between the third source/drain feature and the fourth source/drain feature with a second selected width and a second selected depth to define the second shunt path.

In certain embodiments of the method, insulation feature includes a first segment between the first source/drain feature and the second source/drain feature; the functional integrated circuit is a first functional integrated circuit; the transient voltage suppressor is a first transient voltage suppressor; and the method further includes: designing a second functional integrated circuit in electrical communication with a third node and a fourth node; determining a second maximum voltage threshold for the second functional integrated circuit; designing a second transient voltage suppressor as a second shunt path between the third node and the fourth node to discharge a second current having a second voltage exceeding the second maximum voltage threshold, wherein the second shunt path passes from a third source/drain feature to a fourth source/drain feature through the semiconductor material under a second segment of the insulation feature; forming the third source/drain feature and the fourth source/drain feature over the semiconductor material, wherein the third source/drain feature is distanced from the fourth source/drain feature in the first direction; and forming the second segment of the insulation feature between the third source/drain feature and the fourth source/drain feature and forming a third segment of the insulation feature, wherein the third segment is perpendicular to the first segment and to the second segment, and wherein the third segment interconnects the first segment and the second segment.

In another embodiment, a semiconductor device is provided and includes a first source/drain feature of a first dopant type formed in a substrate of a second dopant type opposite the first dopant type; a second source/drain feature of the first dopant type formed in the substrate; an insulation feature located between the first source/drain feature and the second source/drain feature and extending toward the substrate to a selected depth; a first contact in electrical connection with the first source/drain feature and with a first node; a second contact in electrical connection with the second source/drain feature and with a second node; a functional circuit formed over the substrate; and a voltage discharge circuit extending under the insulation feature and between the first source/drain feature and the second source/drain feature, wherein the voltage discharge circuit is parallel to the functional circuit.

In certain embodiments, the device further includes a first shallow trench isolation (STI) feature; and a second shallow trench isolation (STI) feature; wherein the first source/drain feature is located between the first STI feature and the insulation feature; and the second source/drain feature is located between the second STI feature and the insulation feature.

In certain embodiments, the device further includes a first poly on oxide definition edge (PODE) structure; and a second poly on oxide definition edge (PODE) structure; wherein: the insulation feature is a continuous poly on oxide definition edge (CPODE) structure; the first source/drain feature is located between the first PODE feature and the CPODE feature; and the second source/drain feature is located between the second PODE feature and the CPODE feature.

In certain embodiments, the device further includes a first continuous poly on oxide definition edge (CPODE) structure; and a second continuous poly on oxide definition edge (CPODE) structure; wherein the insulation feature is a central continuous poly on oxide definition edge (CPODE) structure; the first source/drain feature is located between the first CPODE feature and the central CPODE feature; and the second source/drain feature is located between the second CPODE feature and the central CPODE feature.

In certain embodiments, the device further includes a first floating dummy gate; and a second floating dummy gate; wherein the first source/drain feature is located between the first floating dummy gate and the insulation feature; and the second source/drain feature is located between the second floating dummy gate and the insulation feature.

In certain embodiments of the device, the first source/drain feature and the second source/drain feature are distanced from one another in a first direction and define a first axis; the semiconductor device further includes a third source/drain feature and a fourth source/drain feature distanced from one another in the first direction and defining a second axis distanced from the first axis in a second direction perpendicular to the first direction; the first contact is in electrical connection with the third source/drain feature; the second contact is in electrical connection with the fourth source/drain feature; and the insulation feature is located between the third source/drain feature and the fourth source/drain feature.

In certain embodiments of the device, the first source/drain feature and the third source/drain feature are merged together; and the second source/drain feature and the fourth source/drain feature are merged together.

In certain embodiments of the device, the first source/drain feature and the third source/drain feature are separated from one another; and the second source/drain feature and the fourth source/drain feature are separated from one another.

In certain embodiments of the device, the first source/drain feature and the second source/drain feature are distanced from one another in a first direction and define a first axis; the semiconductor device further includes a third source/drain feature and a fourth source/drain feature distanced from one another in the first direction and defining a second axis distanced from the first axis in a second direction perpendicular to the first direction; the insulation feature is a first insulation feature; and the semiconductor device further includes a second insulation feature located between the third source/drain feature and the fourth source/drain feature and extending toward the substrate to a second selected depth.

In certain embodiments of the device, the first source/drain feature and the second source/drain feature are distanced from one another in a first direction and define a first axis; the semiconductor device further includes a third source/drain feature and a fourth source/drain feature distanced from one another in the first direction and defining a second axis parallel to the first axis; the insulation feature includes a first insulation feature segment and a second insulation feature segment; the first insulation feature segment has a first width in the first direction; the second insulation feature segment has a second width in the first direction; the first insulation feature segment is located between the first source/drain feature and the second source/drain feature; and the second insulation feature segment is located between the third source/drain feature and the fourth source/drain feature.

In certain embodiments of the device, the first source/drain feature and the second source/drain feature are distanced from one another in a first direction and define a first axis; the semiconductor device further includes a third source/drain feature and a fourth source/drain feature distanced from one another in the first direction and defining a second axis distanced from the first axis in a second direction perpendicular to the first direction; the insulation feature includes a first insulation feature segment and a second insulation feature segment interconnected by a third insulation feature segment; the first insulation feature segment extends in the second direction and is located between the first source/drain feature and the second source/drain feature; the second insulation feature segment extends in the second direction and is located between the third source/drain feature and the fourth source/drain feature; and the third insulation feature segment extends in the first direction between the first insulation feature segment and the second insulation feature segment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first source/drain feature and a second source/drain feature over a substrate, wherein the first source/drain feature and the second source/drain feature are separated by a gate structure;
removing the gate structure to form a trench;
forming an insulation feature in the trench; and
forming a functional circuit over the substrate, wherein a shunt path parallel to the functional circuit is defined under the insulation feature and between the first source/drain feature and the second source/drain feature.

2. The method of claim 1, wherein:
the first source/drain feature and the second source/drain feature define a first axis;
the method further comprises forming a third source/drain feature and a fourth source/drain feature separated by the gate structure; and
the third source/drain feature and the fourth source/drain feature define a second axis parallel to the first axis.

3. The method of claim 2, wherein the shunt path is defined under the insulation feature, between the first source/drain feature and between the third source/drain feature and the fourth source/drain feature.

4. The method of claim 2, wherein:
the functional circuit is a first functional circuit;
the method comprises forming a second functional circuit over the substrate; and
a second shunt path parallel to the second functional circuit is defined under the insulation feature and between the third source/drain feature and the fourth source/drain feature.

5. A method comprising:
designing a functional integrated circuit in electrical communication with a first node and a second node;
determining a maximum voltage threshold or a maximum current threshold for the functional integrated circuit;
designing a transient voltage suppressor as a shunt path between the first node and the second node to discharge a current exceeding the maximum current threshold and/or having a voltage exceeding the maximum voltage threshold, wherein the shunt path passes from a first source/drain feature to a second source/drain feature through a semiconductor material under an insulation feature having a selected width in a first direction and selected depth;
forming the first source/drain feature and the second source/drain feature over the semiconductor material, wherein the first source/drain feature is distanced from the second source/drain feature in the first direction; and
forming the insulation feature between the first source/drain feature and the second source/drain feature with the selected width and the selected depth to define the shunt path.

6. The method of claim 5, wherein:
the shunt path is a first shunt path passing from the first source/drain feature to the second source/drain feature;
the transient voltage suppressor includes the first shunt path and a second shunt path between the first node and the second node, wherein the second shunt path passes from a third source/drain feature to a fourth source/drain feature through the semiconductor material under the insulation feature;
the method further comprises forming the third source/drain feature and the fourth source/drain feature over the semiconductor material, wherein the third source/drain feature is distanced from the fourth source/drain feature in the first direction; and
forming the insulation feature comprises forming the insulation feature between the third source/drain feature and the fourth source/drain feature.

7. The method of claim 5, wherein:
the functional integrated circuit is a first functional integrated circuit;
the transient voltage suppressor is a first transient voltage suppressor; and
the method further comprises:
designing a second functional integrated circuit in electrical communication with a third node and a fourth node;
determining a second maximum voltage threshold for the second functional integrated circuit;
designing a second transient voltage suppressor as a second shunt path between the third node and the fourth node to discharge a second current having a second voltage exceeding the second maximum voltage threshold, wherein the second shunt path passes from a third source/drain feature to a fourth source/drain feature through the semiconductor material under the insulation feature having a selected width in a first direction and selected depth;
forming the third source/drain feature and the fourth source/drain feature over the semiconductor material, wherein the third source/drain feature is distanced from the fourth source/drain feature in the first direction; and
forming the insulation feature between the third source/drain feature and the fourth source/drain feature with a second selected width and a second selected depth to define the second shunt path.

8. The method of claim 5, wherein
insulation feature includes a first segment between the first source/drain feature and the second source/drain feature;
the functional integrated circuit is a first functional integrated circuit;
the transient voltage suppressor is a first transient voltage suppressor; and
the method further comprises:
designing a second functional integrated circuit in electrical communication with a third node and a fourth node;
determining a second maximum voltage threshold for the second functional integrated circuit;
designing a second transient voltage suppressor as a second shunt path between the third node and the fourth node to discharge a second current having a second voltage exceeding the second maximum voltage threshold, wherein the second shunt path passes from a third source/drain feature to a fourth source/drain feature through the semiconductor material under a second segment of the insulation feature having a second selected width in the first direction and second selected depth;
forming the third source/drain feature and the fourth source/drain feature over the semiconductor material, wherein the third source/drain feature is distanced from the fourth source/drain feature in the first direction; and
forming the second segment of the insulation feature between the third source/drain feature and the fourth source/drain feature with a second selected width and a second selected depth to define the second shunt path.

9. The method of claim 5, wherein:
insulation feature includes a first segment between the first source/drain feature and the second source/drain feature;
the functional integrated circuit is a first functional integrated circuit;
the transient voltage suppressor is a first transient voltage suppressor; and
the method further comprises:
designing a second functional integrated circuit in electrical communication with a third node and a fourth node;
determining a second maximum voltage threshold for the second functional integrated circuit;
designing a second transient voltage suppressor as a second shunt path between the third node and the fourth node to discharge a second current having a second voltage exceeding the second maximum voltage threshold, wherein the second shunt path passes from a third source/drain feature to a fourth source/drain feature through the semiconductor material under a second segment of the insulation feature;
forming the third source/drain feature and the fourth source/drain feature over the semiconductor material, wherein the third source/drain feature is distanced from the fourth source/drain feature in the first direction; and
forming the second segment of the insulation feature between the third source/drain feature and the fourth source/drain feature and forming a third segment of the insulation feature, wherein the third segment is perpendicular to the first segment and to the second segment, and wherein the third segment interconnects the first segment and the second segment.

10. A semiconductor device comprising:
a first source/drain feature of a first dopant type formed in a substrate of a second dopant type opposite the first dopant type;
a second source/drain feature of the first dopant type formed in the substrate;
an insulation feature located between the first source/drain feature and the second source/drain feature and extending toward the substrate to a selected depth;
a first contact in electrical connection with the first source/drain feature and with a first node;
a second contact in electrical connection with the second source/drain feature and with a second node;
a functional circuit formed over the substrate; and
a voltage discharge circuit extending under the insulation feature and between the first source/drain feature and the second source/drain feature, wherein the voltage discharge circuit is parallel to the functional circuit.

11. The semiconductor device of claim 10, further comprising:
a first shallow trench isolation (STI) feature; and
a second shallow trench isolation (STI) feature; wherein:
the first source/drain feature is located between the first STI feature and the insulation feature; and
the second source/drain feature is located between the second STI feature and the insulation feature.

12. The semiconductor device of claim 10, further comprising:
a first poly on oxide definition edge (PODE) structure; and
a second poly on oxide definition edge (PODE) structure; wherein:
the insulation feature is a continuous poly on oxide definition edge (CPODE) structure;
the first source/drain feature is located between the first PODE feature and the CPODE feature; and
the second source/drain feature is located between the second PODE feature and the CPODE feature.

13. The semiconductor device of claim 10, further comprising:
a first continuous poly on oxide definition edge (CPODE) structure; and
a second continuous poly on oxide definition edge (CPODE) structure; wherein:
the insulation feature is a central continuous poly on oxide definition edge (CPODE) structure;
the first source/drain feature is located between the first CPODE feature and the central CPODE feature; and
the second source/drain feature is located between the second CPODE feature and the central CPODE feature.

14. The semiconductor device of claim 10, further comprising:
a first floating dummy gate; and
a second floating dummy gate; wherein:
the first source/drain feature is located between the first floating dummy gate and the insulation feature; and
the second source/drain feature is located between the second floating dummy gate and the insulation feature.

15. The semiconductor device of claim 10, wherein:
the first source/drain feature and the second source/drain feature are distanced from one another in a first direction and define a first axis;
the semiconductor device further comprises a third source/drain feature and a fourth source/drain feature distanced from one another in the first direction and defining a second axis distanced from the first axis in a second direction perpendicular to the first direction;
the first contact is in electrical connection with the third source/drain feature;
the second contact is in electrical connection with the fourth source/drain feature; and
the insulation feature is located between the third source/drain feature and the fourth source/drain feature.

16. The semiconductor device of claim 15, wherein:
the first source/drain feature and the third source/drain feature are merged together; and
the second source/drain feature and the fourth source/drain feature are merged together.

17. The semiconductor device of claim 15, wherein:
the first source/drain feature and the third source/drain feature are separated from one another; and
the second source/drain feature and the fourth source/drain feature are separated from one another.

18. The semiconductor device of claim 10, wherein:
the first source/drain feature and the second source/drain feature are distanced from one another in a first direction and define a first axis;
the semiconductor device further comprises a third source/drain feature and a fourth source/drain feature distanced from one another in the first direction and defining a second axis distanced from the first axis in a second direction perpendicular to the first direction;
the insulation feature is a first insulation feature; and
the semiconductor device further comprises a second insulation feature located between the third source/drain feature and the fourth source/drain feature and extending toward the substrate to a second selected depth.

19. The semiconductor device of claim 10, wherein:
the first source/drain feature and the second source/drain feature are distanced from one another in a first direction and define a first axis;
the semiconductor device further comprises a third source/drain feature and a fourth source/drain feature distanced from one another in the first direction and defining a second axis parallel to the first axis;
the insulation feature includes a first insulation feature segment and a second insulation feature segment;
the first insulation feature segment has a first width in the first direction;
the second insulation feature segment has a second width in the first direction;
the first insulation feature segment is located between the first source/drain feature and the second source/drain feature; and
the second insulation feature segment is located between the third source/drain feature and the fourth source/drain feature.

20. The semiconductor device of claim 10, wherein:
the first source/drain feature and the second source/drain feature are distanced from one another in a first direction and define a first axis;
the semiconductor device further comprises a third source/drain feature and a fourth source/drain feature distanced from one another in the first direction and defining a second axis distanced from the first axis in a second direction perpendicular to the first direction;
the insulation feature includes a first insulation feature segment and a second insulation feature segment interconnected by a third insulation feature segment;
the first insulation feature segment extends in the second direction and is located between the first source/drain feature and the second source/drain feature;
the second insulation feature segment extends in the second direction and is located between the third source/drain feature and the fourth source/drain feature; and
the third insulation feature segment extends in the first direction between the first insulation feature segment and the second insulation feature segment.
